(19) United States
(12) Patent Application Publication
(10) Pub. No.: US 2018/0306846 A1
(43) Pub. Date: Oct. 25, 2018

(54) NON-CONTACT ELECTRICITY METERS

(71) Applicant: The Regents of the University of California, Oakland, CA (US)

(72) Inventors: Steven M. Lanzisera, Oakland, CA (US); Douglas R. Black, Oakland, CA (US)

(21) Appl. No.: 15/527,296

(22) PCT Filed: Nov. 18, 2015
(86) PCT No.: PCT/US2015/061426

§ 371 Date: May 16, 2017

Related U.S. Application Data
(60) Provisional application No. 62/082,994, filed on Nov. 21, 2014.

(51) Int. Cl. G01R 19/25; G01R 33/02; G01R 19/165

(52) U.S. Cl. CPC G01R 19/2513; G01R 19/1659; G01R 33/02

(57) ABSTRACT

The present disclosure provides for a device which is a non-contact metering of a current, a voltage, power, and/or energy.

### CROSS-REFERENCE TO RELATED APPLICATIONS

This application claims the benefit of U.S. Provisional Patent Application No. 62/082,994, filed Nov. 21, 2014, and titled “Non-Contact Electricity Meters”, which is incorporated by reference herein in its entirety and for all purposes.

### STATEMENT OF GOVERNMENTAL SUPPORT

The invention was made with government support under Contract No. DE-AC02-05CH11231 awarded by the U.S. Department of Energy. The government has certain rights in the invention.

### FIELD OF THE DISCLOSURE

The present disclosure is in the field of electricity meters.

### BACKGROUND OF THE DISCLOSURE

Currently an electrician must do live electrical work (or shut a building's power) to install an electricity meter. What is not currently available is a metering electronics device which can be installed by one who is not an electrician, without live electrical work, and without the need to install conduit or other safety devices. Such a device would enable all debugging and maintenance to be performed by a non-electrician and thus reduce cost and speed deployment and maintenance.

### SUMMARY OF THE DISCLOSURE

The systems, methods and devices of this disclosure each have several innovative aspects, no single one of which is solely responsible for the desirable attributes disclosed herein. Included among these aspects are at least the following implementations, although further implementations may be set forth in the detailed description or may be evident from the discussion provided herein.

In some embodiments, a non-contact metering device configured to determine a current may be provided. The non-contact metering device may include one or more magnetic field sensors and a signal processing electronic unit. The one or more magnetic field sensors may be electrically connected to the signal processing electronic unit, each of the one or more magnetic field sensors may be for providing a first measurement of a first magnitude of a magnetic field in a first direction at a first location, as a first signal to the signal processing electronic unit, each first location may be different from any other first location, and the signal processing electronic unit may be for determining the current using the first signal from the one or more magnetic field sensors.

In some such embodiments, the non-contact metering device may further include two or more magnetic field sensors. A first magnetic field sensor may be for providing a first measurement of a first magnitude of the magnetic field in a first direction at a first location, as a first signal to the signal processing electronic unit, a second magnetic field sensor may be for providing a second measurement of a second magnitude of the magnetic field in a second direction at a second location, as a second signal to the signal processing electronic unit, and the signal processing electronic unit may be for determining the current using the first signal and the second signal.

In some further such embodiments, the non-contact metering device may further include an amplifier electrically interposed between the two or more magnetic field sensors and the signal processing electronic unit, and the amplifier may be for amplifying the first signal and the second signal.

In some further such embodiments, the non-contact metering device may further include a filter electrically interposed between the two or more magnetic field sensors and the signal processing electronic unit, and the filter may be for filtering the first signal and the second signal.

In some further such embodiments, the non-contact metering device may further include an analog to digital electronic unit electrically interposed between the two or more magnetic field sensors and the signal processing electronic unit. The digital electronic unit may be for converting the first signal to a first digital signal and the second signal to a second digital signals, and the signal processing electronic unit may be for determining the current using the first digital signal and the second digital signal.

In one such embodiment, the non-contact metering device may further include an analog signal processing electronic unit electrically interposed between the two or more magnetic field sensors and the signal processing electronic unit, and the analog signal processing unit may be for amplifying the first signal and the second signal and for filtering the first signal and the second signal, while preserving the phase characteristics of the first signal and the second signal.

In further such embodiments, the non-contact metering device may further include an analog to digital interface electronic unit electrically interposed between the analog signal processing electronic unit and the signal processing electronic unit, and the analog to digital interface electronic unit may be for converting the first signal to a first digital signal and the second signal to a second digital signal.

In some further such embodiments, the analog to digital interface electronic unit may be for sampling the two or more magnetic field sensors in a time window that is limited by the allowable phase resolution error in the device.

In one further embodiment, the second magnetic field sensor may be offset from the first magnetic field sensor by a first distance.

In further such embodiments, the non-contact metering device may further include a third magnetic field sensor. The third magnetic field sensor may be for providing a third measurement of a third magnitude of the magnetic field in a third direction at a third location, as a third signal to the signal processing electronic unit, and the third magnetic field sensor may be offset from the first magnet field sensor by a third distance that is orthogonal to the first distance.

In some embodiments, the non-contact metering device may further include a voltage sensor. The voltage sensor may be electrically connected to the signal processing electronic unit, the voltage sensor may be for providing a first measurement of the voltage as a third signal to the signal processing electronic unit, and the signal processing electronic unit may be for determining the voltage using the third signal from the electric field sensor.

In some further such embodiments, the voltage sensor may be an electric field sensor that may include a sense electrode and one or more shield electrodes. The voltage sensor may be for providing a first measurement of the electric field as a third signal to the signal processing unit and the one or more shield capacitors electrodes may be for blocking electric field interference from one or more other voltage sources.

In some embodiments, the non-contact metering device may further include a communications and power interface electronic unit that may be for providing communication to one or more external devices.

In some embodiments, the non-contact metering device may further include a non-volatile data storage that may be for logging the first measurements, the second measurements, and the determined current.

In some embodiments, the non-contact metering device may further include a connection for a battery that may be for making a local structural equation modeling (“SEM”) of a single breaker data logger.

In one embodiment, a system for non-contact metering of one or more conductors may be provided. The system may include a non-contact metering device that may be configured to determine a current, including two or more magnetic field sensors, a memory, and a controller comprising control logic for: (a) causing a first magnetic field sensor to take a first sample of a first magnitude of a magnetic field in a first direction at a first location, (b) causing a second magnetic field sensor to take a second sample of a second magnitude of the magnetic field in a second direction at a second location, (c) multiplying the first sample by a first coefficient from a magnetic field model, (d) multiplying the second sample by a second coefficient from the magnetic model, (e) determining a current using (c) and (d), and (f) storing the current in the memory. The non-contact metering device may be communicatively connected to the controller and the controller may be communicatively connected to the memory.

In some embodiments, the controller may further include control logic for: (g) adjusting the first sample for a first direct current (DC) offset, and (h) adjusting the second sample for a second DC offset.

In one such embodiment, the controller may further include control logic for: (i) multiplying the first sample by a first coefficient from an interference model, (j) multiplying the second sample by a second coefficient from the interference model, (k) determining an interference measurement using (i) and (j), and (l) storing the interference measurement in the memory.

In further such embodiments, the controller may further include control logic for: (m) repeating one or more of (a) through (f) and (i) through (l), (n) determining one or more step changes between two or more of the currents stored in the memory, (o) determining one or more step changes between two or more of the interference measurements stored in the memory, (p) in (c), using a third coefficient from the magnetic field model, based upon the determining in (n), (q) in (d), using a fourth coefficient from the magnetic field model, based upon the determining in (n), (r) in (i), using a third coefficient from the interference model, based upon the determining in (n), (s) in (j), using a fourth coefficient from the interference model, based upon the determining in (o), (t) storing the first coefficient, second coefficient, third coefficient, and fourth coefficient from the magnetic field model in the memory, (u) storing the first coefficient, second coefficient, third coefficient, and fourth coefficient from the interference model in the memory, (v) storing the one or more step changes determined in (n), (w) storing the one or more step changes determined in (o), and (x) selecting a fifth coefficient for (c) and a sixth coefficient for (d) based at least in part upon one or more of the currents stored in the memory, the interference measurements stored in the memory, the coefficients from the magnetic field model stored in the memory, or the coefficients from the interference model stored in the memory.

In one such embodiment, the non-contact metering device configured to determine a current may also be configured to determine a voltage, and may further includes a voltage sensor. The controller also further includes control logic for: (y) causing the voltage sensor to take a first sample of a voltage, and (z) determining a first power measurement using the current and the first sample of the voltage.

In further such embodiments, the voltage sensor may include an electric field sensor, including a sense electrode and one or more shield electrodes. The controller also further includes control logic for: in (y), causing the voltage sensor to take a first sample of a rate of change of the voltage, (aa) determining the voltage using the rate of change of the voltage from (y), and (bb) determining a first power measurement using the current and the voltage from (aa).

In some embodiments, a non-contact metering device configured to determine a voltage may be provided. The non-contact metering device may include an electric field sensor that may include a sense electrode and one or more shield electrodes, and a signal processing electronic unit. The electric field sensor may be electrically connected to the signal processing electronic unit, the electric field sensor may be for providing a first measurement of the electric field as a first signal to the signal processing unit, the one or more shield electrodes may be for blocking electric field interference from one or more other voltage sources, and the signal processing electronic unit may be for determining the voltage using the third signal from the electric field sensor.

In some embodiments, a method for metering may be provided. The method may include: (a) causing a first magnetic field sensor to take a first sample of a first magnitude of a magnetic field in a first direction at a first location, (b) causing a second magnetic field sensor to take a second sample of a second magnitude of the magnetic field in a second direction at a second location, (c) multiplying the first sample by a first coefficient from a magnetic field model, (d) multiplying the second sample by a second coefficient from the magnetic model, (e) determining a current using (c) and (d), and (f) storing the current in a memory. A non-contact metering device may be communicatively connected to a controller, and the controller may be communicatively connected to the memory.

In some further embodiments, the method may further include: (g) adjusting the first sample for a first direct current (DC) offset, and (h) adjusting the second sample for a second DC offset.

In one such embodiment, the method may further include: (i) multiplying the first sample by a first coefficient from an interference model, (j) multiplying the second sample by a second coefficient from the interference model, (k) determining an interference measurement using (i) and (j), and (l) storing the interference measurement in the memory.

In some further such embodiments, the method may further include: (m) repeating one or more of (a) through (f) and (i) through (l), (n) determining one or more step changes between two or more of the currents stored in the memory, (o) determining one or more step changes between two or more of the interference measurements stored in the memory, (p) in (c), using a third coefficient from the magnetic field model, based upon the determining in (n), (q) in (d), using a fourth coefficient from the magnetic field model, based upon the determining in (n), (r) in (i), using a third coefficient from the interference model, based upon the determining in (n), (s) in (j), using a fourth coefficient from the interference model, based upon the determining in (o), (t) storing the first coefficient, second coefficient, third coefficient, and fourth coefficient from the magnetic field model in the memory, (u) storing the first coefficient, second coefficient, third coefficient, and fourth coefficient from the interference model in the memory, (v) storing the one or more step changes determined in (n), (w) storing the one or more step changes determined in (o), and (x) selecting a fifth coefficient for (c) and a sixth coefficient for (d) based at least in part upon one or more of the currents stored in the memory, the interference measurements stored in the memory, the coefficients from the magnetic field model stored in the memory, or the coefficients from the interference model stored in the memory.

In one such embodiment, the method may further include: (y) causing a voltage sensor to take a first sample of a voltage, (z) determining a first power measurement using the current and the first sample of the voltage.

In some further such embodiments, the method may further include: in (y), causing the voltage sensor to take a first sample of a rate of change of the voltage, (aa) determining the voltage using the rate of change of the voltage from (y), and (bb) determining a first power measurement using the current and the voltage from (aa), and the voltage sensor may include an electric field sensor that includes a sense electrode and one or more shield electrodes.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 depicts an isometric view of a first example embodiment of a non-contact metering device.

FIG. 2 depicts a plane view of a sample illustration of the magnetic field detected by the first example embodiment of the non-contact metering device 100 of FIG. 1.

FIG. 3 depicts a plane view of a second example embodiment of the non-contact metering device.

FIG. 4 depicts a third example embodiment of the non-contact metering device that includes magnetic field sensors arranged in three dimensions.

FIG. 5 depicts an isometric view of a fourth example embodiment of the non-contact metering device that includes magnetic field sensors arranged in three dimensions.

FIG. 6 depicts the device 100 and conductor 116 of FIG. 2 along with a magnetic field generated by a second conductor.

FIG. 7 depicts an isometric view of a fifth example embodiment of the non-contact metering device that includes magnetic field sensors that are arranged to provide measurements of a magnetic field in more than one direction.

FIG. 8 depicts an isometric view of a sixth example embodiment of the non-contact metering device that includes magnetic field sensors that are arranged to provide measurements of a magnetic field in more than two directions.

FIG. 9 shows device 900 including three magnetic field sensors, each being able to detect a magnitude of a magnetic field at a specific location in three different directions.

FIG. 10 depicts an isometric view of a first example electric field sensor.

FIG. 11 depicts an exploded, isometric view of the first example electric field sensor of FIG. 10.

FIG. 12 depicts an example of electrical interference caused to the sense electrode by another conductor.

FIG. 13 depicts an example of the effect of shield electrode on electrical interference caused to the sense electrode by another conductor from FIG. 12.

FIG. 14 depicts an electrical circuit of one example embodiment of an electric field sensor.

FIG. 15 depicts a plane view of a second example electric field sensor on a conductor.

FIG. 16 depicts a cross-sectional view of the second example electric field sensor and the conductor of FIG. 15.

FIG. 17 depicts a schematic of an example embodiment of a non-contact metering device configured to determine a current and a voltage.

FIG. 18 depicts an isometric view of a seventh example non-contact metering device.

FIG. 19 depicts a partially exploded, isometric view of the non-contact metering device of FIG. 18.

FIG. 20 depicts a different isometric view of the non-contact metering device of FIG. 18.

FIG. 21 depicts an isometric view of the non-contact metering device of FIG. 18 installed on a circuit breaker.

FIG. 22 depicts a plane view of the non-contact metering device of FIG. 18 installed on a circuit breaker that is installed in a breaker panel.

FIG. 23 depicts an isometric view of the non-contact metering device of FIG. 18 installed on a circuit breaker of FIG. 21.

FIG. 24 depicts a first example system.

FIG. 25 depicts a flowchart illustrating one example technique of executing control logic items (a) through (f), as described in paragraphs [0127] through [0131].

FIG. 26 depicts a flowchart illustrating one example technique of executing control logic items (a) through (f) and (i) through (l), as described in paragraphs [0132] through [0134].

FIG. 27 depicts a flowchart illustrating one example technique of executing control logic items (a) through (f) and (i) through (w), as described in paragraphs [0135] through [0136].

FIG. 28 depicts two graphs showing example results of power estimates calculated using an embodiment of the present disclosure.

### DETAILED DESCRIPTION

It is to be understood that this disclosure is not limited to particular embodiments described, as such may, of course, vary. It is also to be understood that the terminology used herein is for the purpose of describing particular embodiments only, and is not intended to be limiting, since the scope of the presently claimed invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the disclosure. The upper and lower limits of these smaller ranges may independently be included or excluded in the range, and each range where either, neither or both limits are included in the smaller ranges is also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can be used, the preferred methods and materials are now described. All publications mentioned herein are incorporated herein by reference to disclose and describe the methods and/or materials in connection with which the publications are cited.

As used in the specification and the appended claims, the singular forms “a”, “an”, and “the” include plural references unless the context clearly dictates otherwise. Thus, for example, reference to a “truss” includes a single truss as well as a plurality of trusses.

The terms “optional” or “optionally” as used herein mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

These and other objects, advantages, and features of the disclosure will become apparent to those persons skilled in the art upon reading the details of the disclosure as more fully described below. Currently, traditional electricity meters measure currents with current transformers (“CTs”, a non-contact sensor), but voltage is measured with a direct electrical connection. Making this connection generally involves a person, usually an electrician, performing live electrical work on the conductor and/or shutting down the electricity to the conductor on which the measurement. This work may be dangerous, disruptive, inconvenient, and/or costly to perform. A non-contact voltage sensor that can be installed similarly to CTs or in some other simple arrangements would significantly reduce the installation costs, as well as the hazards associated with installation, of electricity meters.

The present inventors have developed a novel device that provides for non-intrusive metering of one or more conductors. As described in greater detail below, this device may include, at least in part, one or more sensors which may sense a magnetic field that may be generated by a current flowing through one or more conductors, and/or one or more sensors that may sense an electric field generated by a voltage on a conductor. As used herein, a “non-contact metering device” may be a device that may measure and/or determine a current, a voltage, power, energy, and/or both a current and a voltage, of one or more conductors.

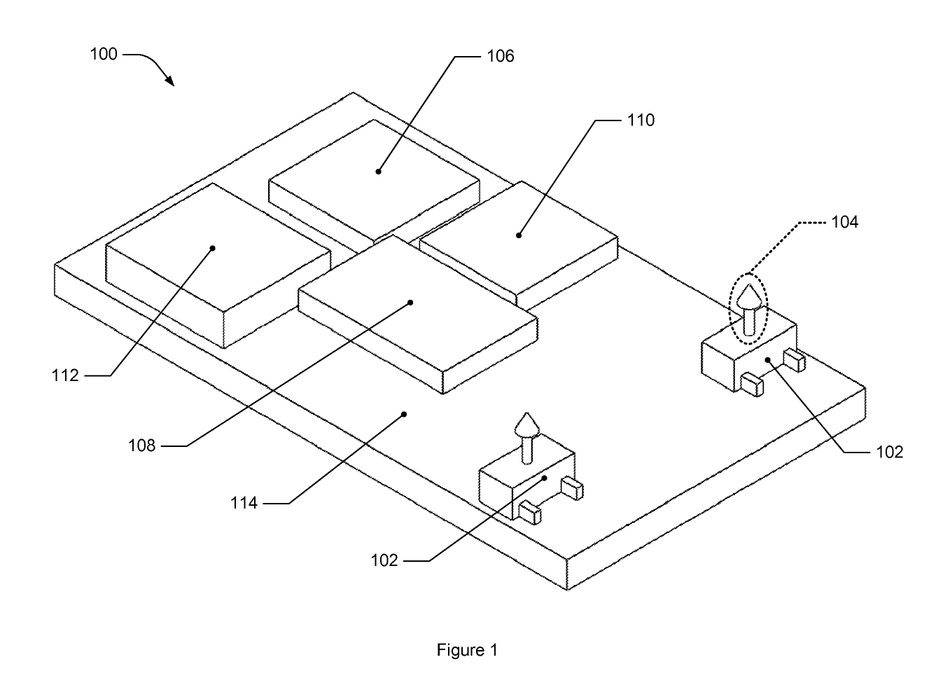

A first example embodiment of the non-contact metering device (hereinafter “the device”) is shown in FIG. 1. FIG. 1 depicts an isometric view of a first example embodiment of a non-contact metering device. As can be seen, the device 100 includes two magnetic field sensors 102, a signal processing electronic unit 106, an analog signal conditioner 108, an analog to digital electronic unit 110, and a communications and power interface electronic unit 112. Two or more of these aforementioned items may be electrically connected to each other, which may be, for instance, a a circuit board 114. In some embodiments the device 100 may include an integrated circuit that may electrically connect two or more items of the device. For example, the one or more magnetic field sensors 102 may be electrically connected to the signal processing electronic unit 106.

The magnetic field sensors 102 may be configured to detect a magnitude of a magnetic field in a direction at a location, and/or may provide a measurement of the magnitude of the magnetic field in a direction at a location as a signal to the signal processing electronic unit 106. For instance, in FIG. 1, each of the magnetic field sensors 102 may be configured to detect a magnitude of a magnetic field in a direction which is represented by a directional arrow 104. As shown in FIG. 1, the magnetic field sensors 102 are configured to detect a magnitude of a magnetic field in a direction that is normal to the circuit board 114. As discussed in greater below, the magnetic field sensors 102 may be able to detect a magnitude of a magnetic field in other and/or more than one directions.

The magnetic field sensor 102 may be any device configured to detect a magnetic field. In some embodiments, the magnetic field sensor 102 may be a sensor described in U.S. Pat. Nos. 4,853,639 and/or 5,617,020, both of which are incorporated herein by reference. In some embodiments, for instance, the magnetic field sensor 102 may be a Hall Effect sensor, a magnetometer, and/or a MEMS magnetic field sensor.

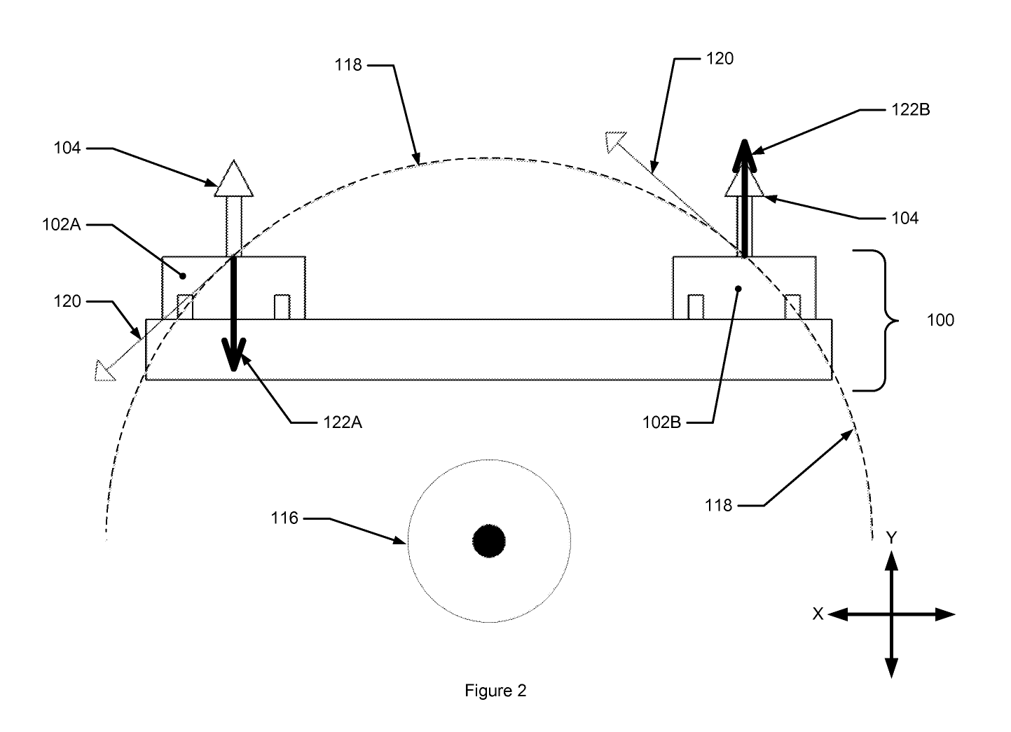

FIG. 2 depicts a plane view of a sample illustration of the magnetic field detected by the first example embodiment of the non-contact metering device 100 of FIG. 1. FIG. 2 shows a conductor 116 from a perspective looking parallel to the conductor 116 and parallel to the direction of a current. According to Ampere's law, the current flowing through the conductor 116 produces a magnetic field 118 that rotates around the conductor 116 in a specific direction, which is counterclockwise in FIG. 2, such that at any point in space, the magnetic field 118 is a magnitude in a direction, which is represented by a vector. Accordingly, the magnetic field 118 surrounding a conductor is a field of vectors. Each vector may include components that have magnitudes in two orthogonal directions, such as an x- and a y-component. For instance, in FIG. 2, two magnetic field vectors 120 can be seen and each may have two vector components, e.g., a magnitude in the x-direction of FIG. 2 and a magnitude in the y-direction.

Accordingly, in some such embodiments, a plurality of magnetic field sensors over a small area may measure a “map” of the magnetic field in two and/or three dimensional space, which may enable field magnitude, direction, and/or gradients to be captured which, in turn, enable orientation, conductor geometry, and/or error sources to be electronically compensated automatically. By doing so, an accurate estimate of the true current is possible without in-the-field calibration of the sensor.

The device 100 in FIG. 2 is located parallel to the conductor 116, and the device 100 includes two magnetic field sensors labeled as 102A and 102B1, each of which is located on the device 100 such that their direction of sensing, represented by the directional arrows 104, is perpendicular to the direction of current in the conductor 116, and in the y-direction of FIG. 2. Each of the two magnetic field sensors may detect a magnitude of the magnetic field 118 in the sensor's direction of sensing, indicated by directional arrow 104, which may be a component of the magnetic field in a specific direction. This may be referred to as a magnitude of the magnetic field in a direction 122. For example, magnetic field sensor 102A is configured to sense the magnitude of the y-directional component 122A of the magnetic field vector 120. In FIG. 2, the y-directional component 122A may be in a “down” or negative y-direction. Similarly, magnetic field sensor 102B is configured to sense the magnitude of the y-directional component 122B of the magnetic field vector 120, which may be in the “up” or positive y-direction. 111

In some embodiments, the magnetic field sensors 102 may be arranged on the device 100 such that each of the magnetic field sensors may provide a measurement of the magnitude of the magnetic field in a specific location, which may be different than the location of the other magnetic field sensors. For instance, in FIG. 2, magnetic field sensor 102A may be at a first location and magnetic field sensor 102B may be at a second location, which may be spatially arranged according to the x-and-y coordinates of FIG. 2. Accordingly, in the example of FIG. 2, magnetic field sensor 102A may provide the magnitude of the magnetic field 118 in the y-direction, e.g. indicated by the sensing directional arrow 104, at the first location, while magnetic field sensor 102B may provide the magnitude of the magnetic field 118 in the y-direction, at the second direction. These measurements may then be sent to the signal processing electronic unit 106.

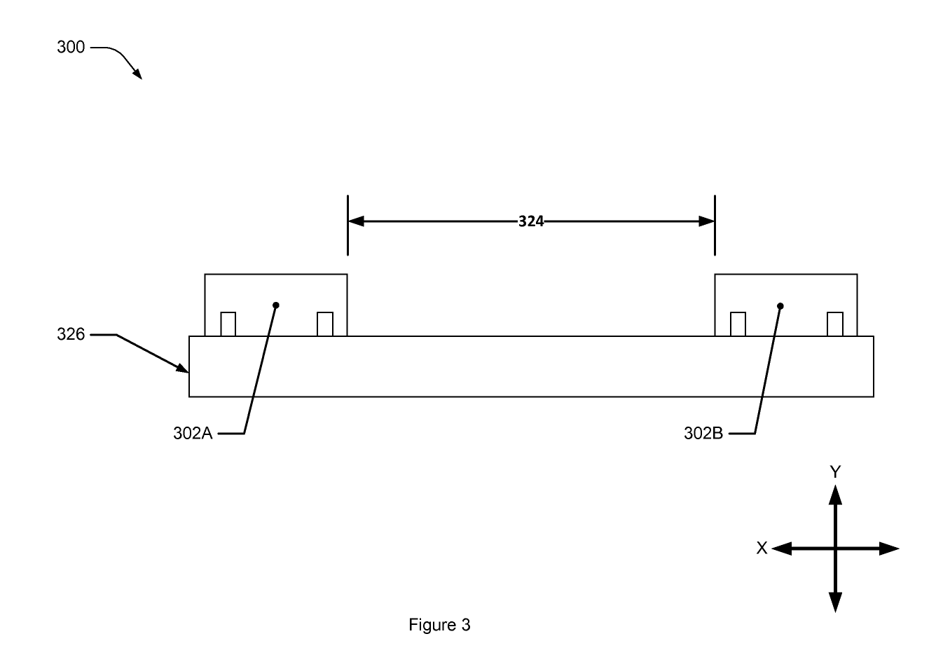

In some embodiments, the magnetic field sensors may be offset from each other by specific distances. FIG. 3 depicts a plane view of a second example embodiment of the non-contact metering device. FIG. 3 shows the device 300 from a perspective normal to a side of the device and includes the x- and y-axes of the device 300. Here, the non-contact metering device 300 includes two magnetic field sensors, and as depicted, a first magnetic sensor 302A is offset from a second sensor 302B by a first distance 324, with the first distance in the x-direction. In some embodiments, the first distance 324 may be in reference to any number of items within the device 300. For example, the first distance 324 may be perpendicular to the sensing direction (not shown) of the magnetic field sensors. In some embodiments, for example, the device 300 may have an outer surface 326 which may be the reference feature for such measurements. In some such embodiments, the outer surface 326 may be oriented such that it may be in the y-direction, as can be seen in FIG. 3. In some such embodiments, the first distance 324 may be perpendicular to the outer surface 326. The outer surface may also be any other surface of the device 100, including, for example, a surface on a housing of the device 100.

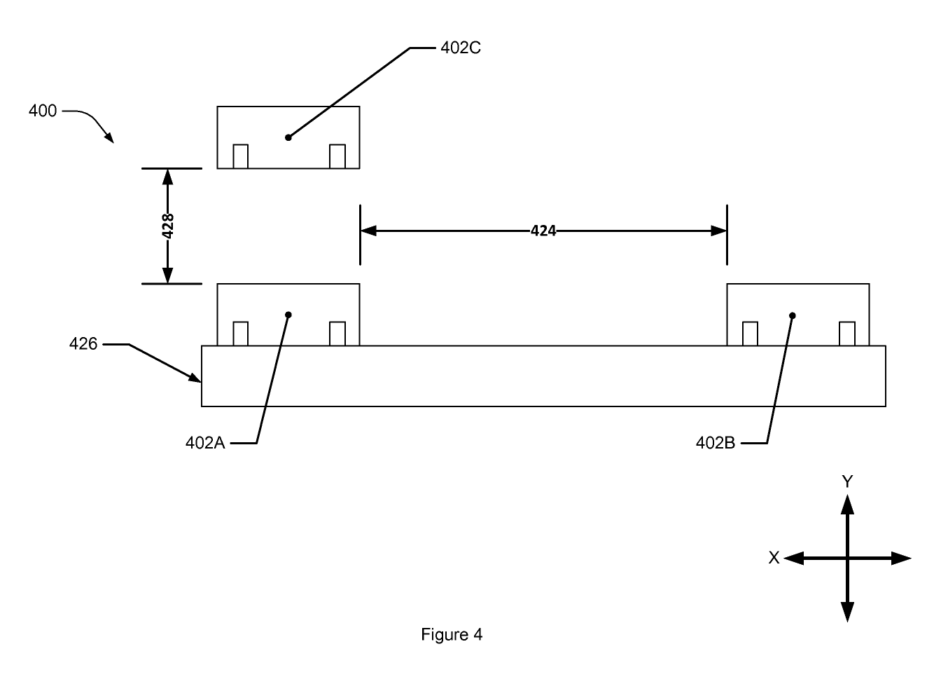

In some other embodiments, the non-contact metering device may also include magnetic field sensors that may be arranged in three dimensions. FIG. 4 depicts a third example embodiment of the non-contact metering device that includes magnetic field sensors arranged in three dimensions. As can be seen, similar to the device in FIG. 3, the device 400 includes a first magnetic field sensor 402A, a second magnetic field sensor 402B, and a third magnetic field sensor 402C. Like in FIG. 3, the first magnetic field sensor 402A is offset from the second magnetic field sensor 402B by a first distance 424, but the third magnetic field sensor 402C is offset from the first magnetic field sensor 402A by a second distance 428 that is orthogonal to the first distance 424. The third magnetic field sensor 402C may also be offset, as in FIG. 4, from the first magnetic field sensor in a direction parallel to the outer surface 426, which may be in the y-direction according to FIG. 4; again, the first distance 424 is in the x-direction. Although not shown in FIG. 4, the third magnetic field sensor 402C may be supported by a feature of the device 400, which may be a support, a second circuit board, an integrated circuit, or any other item of the device 400.

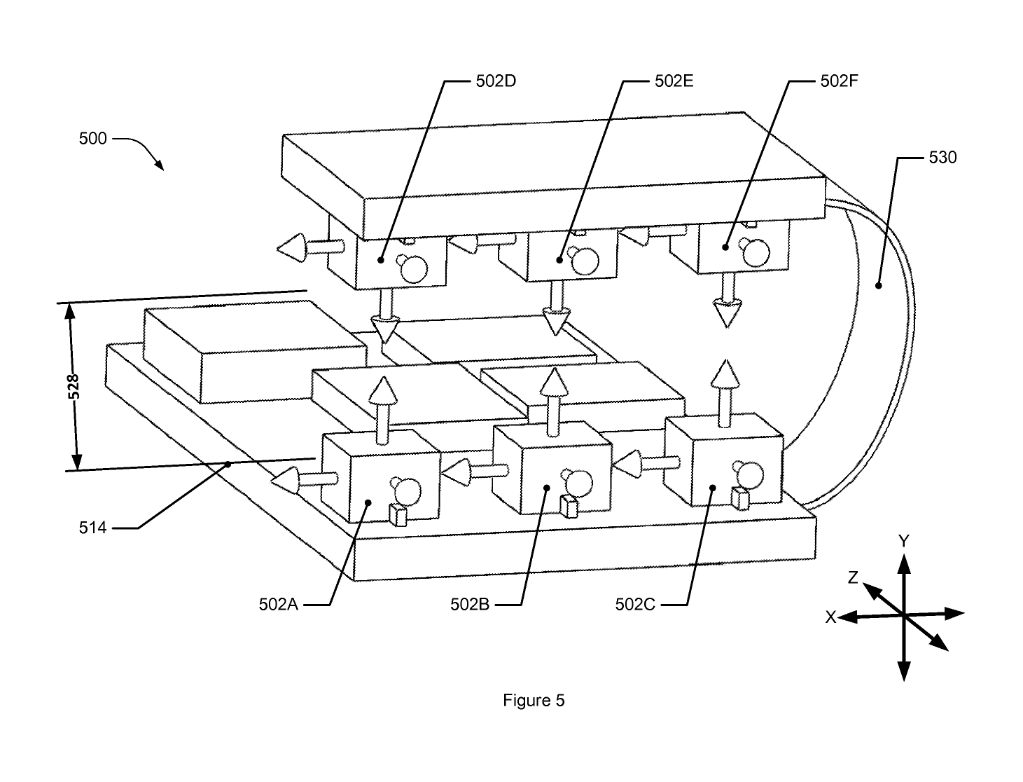

FIG. 5 depicts an isometric view of a fourth example embodiment of the non-contact metering device that includes magnetic field sensors arranged in three dimensions. As can be seen, device 500 includes three magnetic field devices 502A, 502B, and 502C arranged along the circuit board 514 and offset from each other by distances (not labeled) along the x-direction. Device 500 also includes three magnetic field sensors 502D, 502E, and 502F, that are offset from the other three sensors (i.e., 502A, 502B, and 502C) by a second distance 528 in the y-direction, and which are suspended by a support member 530. In some embodiments, the one or more magnetic field sensors may be offset from one or more other magnetic field sensors in the x-, y-, and/or z-directions.

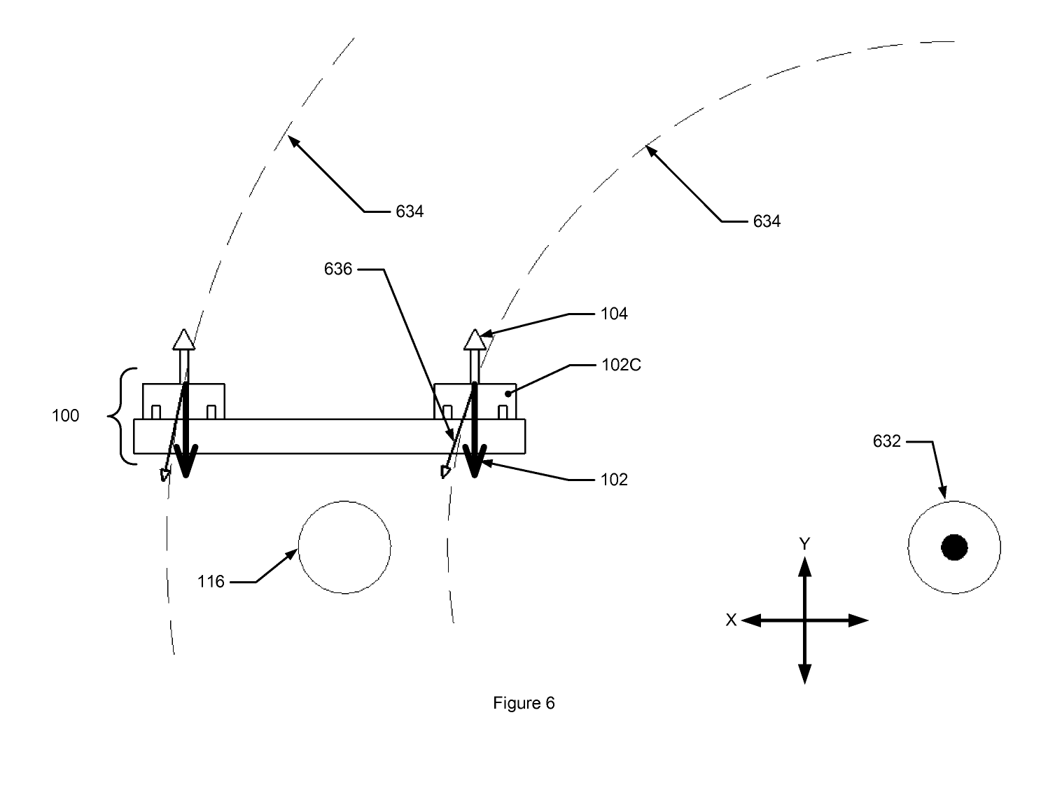

Referring back to FIGS. 1 and 2, the utilization of two or more magnetic field sensors 102 by the device 100 may enable a more accurate and reliable detection of the magnetic field, as well as the potential detection and/or reduction of interference from magnetic fields generated by other conductors. For instance, FIG. 6 depicts the device 100 and conductor 116 of FIG. 2 along with a magnetic field generated by a second conductor. As can be seen, a second conductor 632 may create a magnetic field 634 generally shown with the semicircles labeled 634 and that may be represented by a second magnetic field vector 636. The magnetic field sensor 102B is able to detect a magnetic field in a sensing direction perpendicular to the flow of the current in the second conductor 632, and that is in the y-direction of FIG. 6, as indicated by the directional arrow 104. Here, the magnetic field sensor 102B may be able to provide a measurement of a magnitude of the magnetic field, caused by the second conductor 632, in its sensing direction 622 which may be in the “down” or negative y-direction in FIG. 6.

In some embodiments, the non-contact metering device may include two or more magnetic field sensor that are arranged such that at least one magnetic field sensor may provide a measurement of a magnitude of a magnetic field at a first location in a first direction while at least one other magnetic field sensor may provide a measurement of a magnitude of the magnetic field at a second location in a second direction. FIG. 7 depicts an isometric view of a fifth example embodiment of the non-contact metering device that includes magnetic field sensors that are arranged to provide measurements of a magnetic field in more than one direction. As can be seen, device 700 includes three magnetic field sensors, 702A, 702B, and 702C, with magnetic field sensing in one direction, the y-direction, as represented by the directional arrows 704, such that each magnetic field sensors 702A, 702B, and 702C, may provide a measurement of a magnitude of the magnetic field in the direction of the y-axis in FIG. 7 at each respective sensor's location, as a signal to the signal processing electronic unit (not labeled). Device 700 also includes three other magnetic field sensors, 702D, 702E, and 702F, with magnetic field sensing in one direction, and such direction is different than magnetic field sensors 702A, 702B, and 702C, which in FIG. 7, is in the direction of the x-axis as indicated by second directional arrows 736. Magnetic field sensors 702D, 702E, and 702F, may therefore be able to provide a measurement of a magnitude of the magnetic field in the direction of the x-axis in FIG. 7 at each respective sensor's location, as a signal to the signal processing electronic unit (not labeled). These measurements and/or signals may be used by the signal processing electronic unit to calculate a current of a conductor.

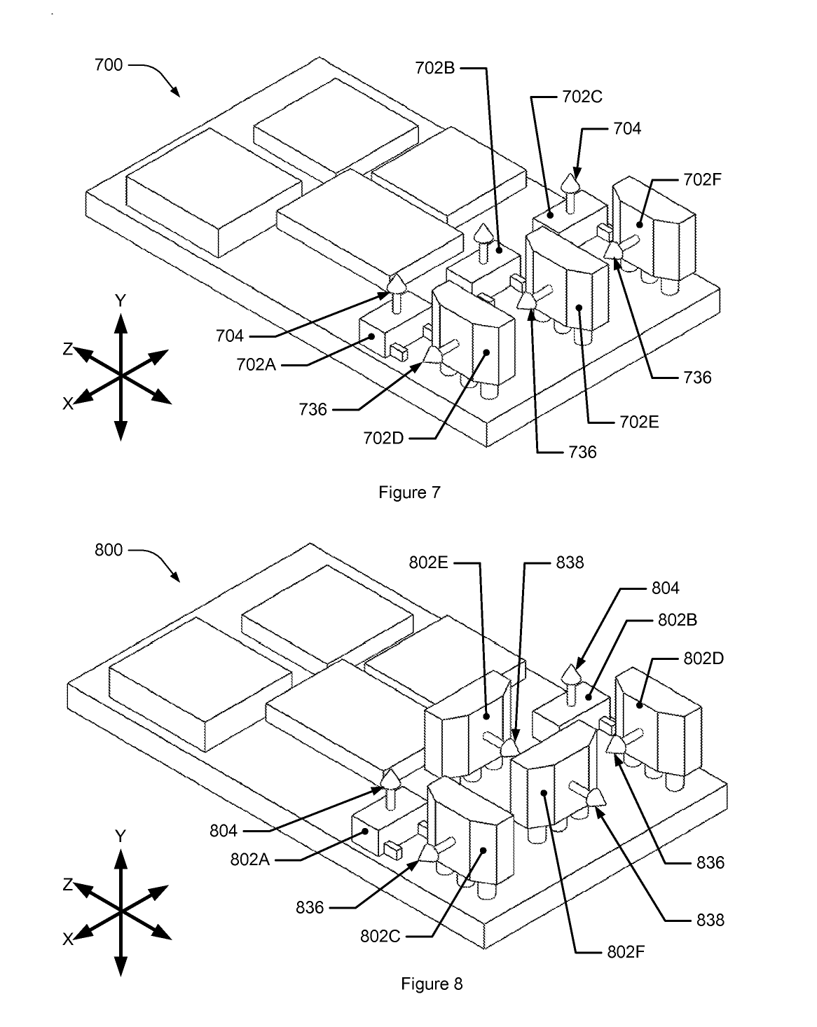

In some embodiments, the non-contact metering device may include three or more magnetic field sensors that are arranged such that at least a first magnetic field sensor may provide a measurement of a magnitude of a magnetic field at a first location in a first direction, at least a second magnetic field sensor may provide a measurement of a magnitude of the magnetic field at a second location in a second direction, and at least a third magnetic field sensor may provide a measurement of a magnitude of the magnetic field at a third location in a third direction. FIG. 8 depicts an isometric view of a sixth example embodiment of the non-contact metering device that includes magnetic field sensors that are arranged to provide measurements of a magnetic field in more than two directions. Similar to FIG. 7, FIG. 8 shows device 800 including six magnetic field sensors, each being able to detect a magnitude of a magnetic field at a specific location in one direction, but such sensors are arranged such that the magnetic field may be measured in three different directions. Magnetic field sensors 802A and 802B are able to sense the magnetic field in one direction, the y-direction, as represented by the directional arrows 804, such that each magnetic field sensor 802A and 802B may provide a measurement of a magnitude of the magnetic field in the direction of the y-axis in FIG. 8 at each respective sensor's location, as a signal to the signal processing electronic unit (not labeled). Magnetic field sensors 802C and 802D are able to sense the magnetic field in one direction, the x-direction, as represented by the directional arrows 836, such that each magnetic field sensor 802C and 802D may provide a measurement of a magnitude of the magnetic field in the direction of the x-axis in FIG. 8 at each respective sensor's location, as a signal to the signal processing electronic unit (not labeled). Finally, magnetic field sensors 802E and 802F are able to sense the magnetic field in one direction, the z-direction, as represented by the directional arrows 838, such that each magnetic field sensor 802E and 802F may provide a measurement of a magnitude of the magnetic field in the direction of the z-axis in FIG. 8 at each respective sensor's location, as a signal to the signal processing electronic unit (not labeled). Accordingly, the signal processing electronic unit of device 800 may receive measurements of a magnitude of the magnetic field in three different directions, as well as such measurements at six different locations.

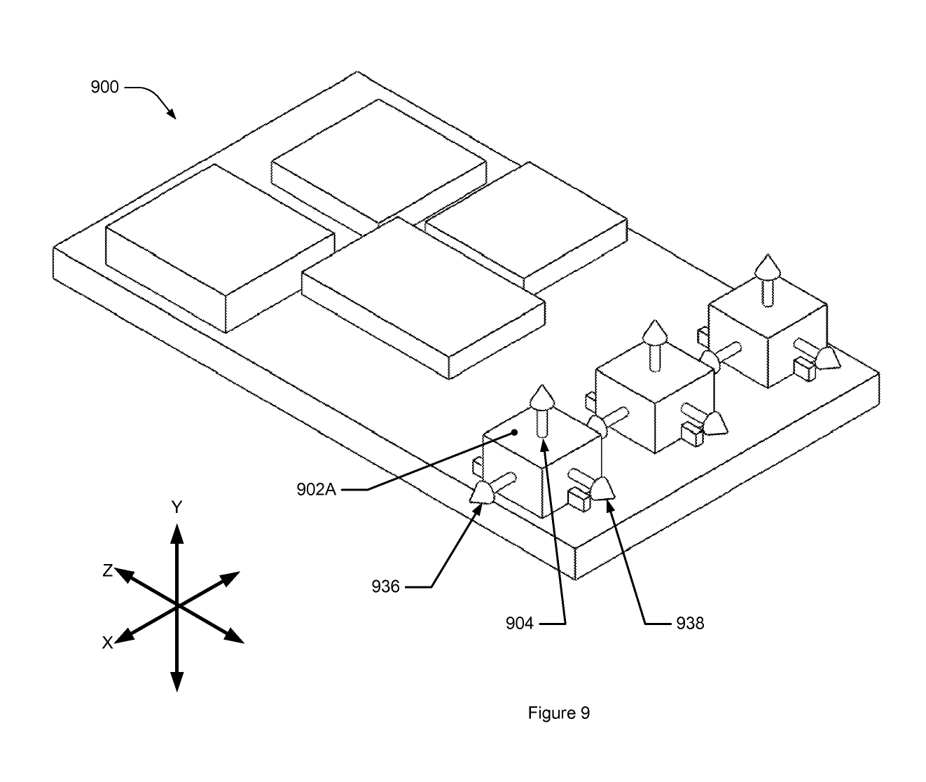

In some embodiments, the non-contact metering device may include one or more magnetic field sensors that may provide a measurement of a magnitude of a magnetic field in more than one direction at a specific location. For example, FIG. 9 shows device 900 including three magnetic field sensors, each being able to detect a magnitude of a magnetic field at a specific location in three different directions. As can be seen, magnetic field sensor 902A is able to provide a measurement of a magnitude of the magnetic field at its location in three different directions: the y-direction as represented by the directional arrow 904, the x-direction as represented by directional arrow 936, and the z-direction as represented by the third directional arrow 938. Therefore, magnetic field sensor 902A may provide a measurement of a first magnitude of the magnetic field in a first direction (e.g., the y-direction) at its location, a measurement of a second magnitude of the magnetic field in a second direction (e.g., the x-direction) at its location, and a measurement of a third magnitude of the magnitude of the magnetic field in a third direction (e.g., the z-direction), as a signal or signals to the signal processing electronic unit (not labeled) in order to determine a current. Each of the other two magnetic field sensors in FIG. 9 may be configured similarly to magnetic field sensor 902A.

In some embodiments, referring back to FIGS. 2 and 6, when a magnetic field is created by both the first conductor 116 and the second conductor 632, the magnetic field created by the second conductor 632 may cause an interference such that the magnetic sensors may detect the vector sum of the magnetic fields. However, with the configurations and embodiments discussed herein, a person of ordinary skill in the art may be able to use the measurements provided by the magnetic field sensors 102 to reduce and/or remove the interference caused by the second conductor 632, or more than the second conductor, and thereby determine a current of the first conductor 116.

Referring back to the device 100 of FIG. 1, in some embodiments, as discussed above, each of the magnetic field sensors may provide a first measurement of a magnitude of a magnetic field in a direction at a location, as a signal to the signal processing electronic unit. In some embodiments, the signal processing electronic unit 106 may be configured to receive such signals and to determine the current based upon these signals, through one or more processes which is known to a person of ordinary skill in the art. For instance, although a person of ordinary skill in the art may be able to determine a current estimate from the measurements provided from one or more magnetic field sensors indicating a first magnitude of a magnetic field in a first direction at a first location in a various ways, such calculations may be achieved, for instance, by using the following formula: I(t)=Σₘ₌₀^{M-1}A_{B}_{ₘ}Bₘ(t)

In this equation, I(t) may represent the optimal estimate of the current, M is the number of magnetic field measurements, Bₘ are the magnetic field measurements provided by the magnetic field sensors 102 at a time (t), and A_{B}_{ₘ} are coefficients which may be based upon the geometry of the magnetic field sensors, the conductor(s), and or the relation between one of the conductors and/or magnetic field sensors, being utilized. Each sensor may be caused to sample, e.g. measure, the magnetic field repeatedly at different times over a specific time period. The A_{B}_{ₘ} coefficients may be developed in a number of ways known to a person of ordinary skill in the art, which may include, for example, simulating a magnetic field for a magnetic field environment or by taking real magnetic field and current measurements, for instance in a lab, and building a model based on such measurements. These coefficients may be stored by a memory and that may be accessed by and utilized by the signal processing electronic unit in order to, among other things, determine a current. For instance, these coefficients may be determined for a particular breaker in a laboratory, and then input to a memory on a non-contact metering device. These coefficients, and another other coefficients discussed herein, may be in the form of a matrix and/or a look-up table, for example.

In one simplified example of determining a current using the aforementioned equation, the device 100 of FIGS. 1 and 2 is used. In this example, M is 2 because there are two magnetic field sensors that each provide one measurement, I(t) is proportional (“α”) to B₁(t)−B₀(t) with A_{B}_{₁}>0, A_{B}_{₁}<0, and |A_{B}_{₁}|≈|A_{B}_{₀}|. Magnetic field sensor 102A may be sampling, e.g., measuring, B₀(t₀) while magnetic field sensor 102B may be sampling B₁(t₁). In this example, t₁−t₀=Δt. In some embodiments, the Δt may be Δt<<T, where T may be a period of time. In some such embodiments, T may be the period of repeated samples of the same sensor output. In some such embodiments, such as for a 60 Hz AC cycle, Δt may be about 0.00001 seconds. In some embodiments, Δt may be more or less than 0.00001 seconds, and it may be adjusted according to the signals of interest in order to obtain, for example, simultaneous representations of the magnetic field at different locations.

In some embodiments, the analog to digital interface electronic unit 110 is configured to and for sampling the one or more magnetic field sensors, which may be, for example in a time window that may be limited by the allowable phase resolution error in the device 100. In some such embodiments, the signal processing electronic unit, a processor, a database, and/or some other item may be configured to and/or for performing such sampling. For example, as discussed above, the device may be configured to and/or capable of sampling, e.g. taking a measurement, of the magnetic field from one or more magnetic field sensors within a specified time or time period, such as 0.00001 seconds.

As stated above, in some embodiments, the device 100 may include two magnetic field sensors 102, a signal processing electronic unit 106, an analog signal conditioner 108, an analog to digital electronic unit 110, and a communications and power interface electronic unit 112. However, in some embodiments, that device 100 may not include one or more of these aforementioned items. For instance, the device 100 may only include two magnetic field sensors 102 and a signal processing unit 102. In some other embodiments, the device 100 may include other items not listed herein, such as additional sensors, a housing, or a power source.

The analog signal conditioner 108 may be configured to provide amplification of a signal from one or more magnetic field sensors, to provide filtering of the signal from the one or more magnetic field sensors, and/or to provide both such filtering and amplification. The device 100 may also include a separate amplifier and/or a filter for such purposes. In some embodiments, the amplification and/or filtering may be performed by analog and/or digital means. Such amplification and/or filtering may also be performed on the device, or on another separate device, such as a server, database, computer, and/or processor.

The analog to digital electronic unit 110 may be configured to convert one or more signals from analog to digital. Such conversion may occur on the device or, similar to above, on a separate device, such as a server, database, computer, and/or processor. This conversion by the analog to digital electronic unit 110 may also occur at any point electrically “downstream” from the one or more magnetic field sensors 102. For example, such conversion may occur immediately before the signals from the one or more magnetic field sensors reach the signal processing electronic unit.

In some embodiments, the device may include elements that utilize and transmit analog signals, digital signals, and/or both analog and digital signals. For example, the magnetic field sensors may provide analog signals which the electronic signal processing unit 106 may be configured to receive and process. In some other embodiments, analog signals from the magnetic field sensors may be converted by the analog to digital electronic unit 110, which then may be transmitted to and received by the signal processing unit 106.

The present disclosure may also provide for a voltage sensor that may, among other things, detect a voltage and may be used for electricity metering applications. In some such embodiments, the present disclosure may only have one or more voltage sensors and no magnetic field sensors. In some embodiments, the voltage sensor may be a sensor connected directly to a live conductor and/or may be a non-contact voltage sensor. An electric metering device may also include just a voltage sensor (e.g., a non-contact voltage sensor), but in other such embodiments, a non-contact metering device may include the non-contact voltage sensor and one or more of the elements discussed above with regard to device 100, including the one or more magnetic field sensors such that the non-contact metering device may determine both a current and a voltage. In some such embodiments, a voltage waveform may be remotely sensed. In some other embodiments, the voltage sensor may be a “contact” type sensor which is directly connected to a voltage source.

In some embodiments, the voltage sensor may be an electric field sensor that may detect a voltage without direct contact to the conductor, e.g. by “non-contact”. The electric field sensor may include one or more capacitive sensor electrodes, and one or more shield electrodes, all of which may be located on, and/or close to a voltage carrying conductor. In some embodiments the voltage sensor may be a plate, which may include one or more layers, that may be applied to a surface of a circuit breaker. The capacitive sensor electrode may be in close proximity to the live voltage in the breaker, but it does not contact the live conductor. The changing electric field induces charge flow on the plate, and this signal may be processed by signal processing electronics.

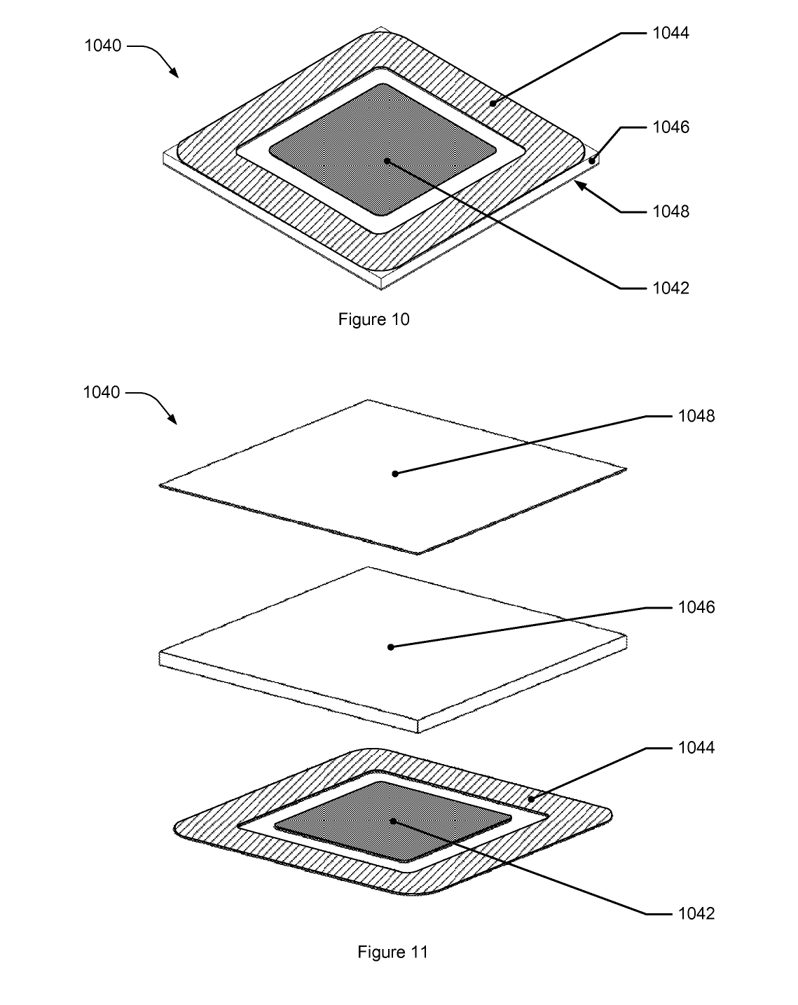

FIG. 10 depicts an isometric view of a first example electric field sensor, while FIG. 11 depicts an exploded, isometric view of the first example electric field sensor of FIG. 10. As can be seen, in FIG. 10, the electric field sensor 1040 is made of several layers which include a sense electrode 1042, a first shield electrode 1044, an insulating layer 1046, and a second shield electrode 1048. As used herein, an “electrode” may be the same as a “capacitor”, such that, for instance, a “shield electrode” may be the same as a “shield capacitor”. The sense electrode 1042, identified with shading, may be within the same layer of the electric field sensor as the first shield electrode 1044, which is identified with crosshatching, such that first shield electrode 1044 surrounds the outer boundary of the sense electrode 1042, as seen in FIG. 10, when viewed from a plane normal to the sense electrode 1042. In some such embodiments, the sense electrode 1042 and the first shield electrode may be coplanar. The sense electrode 1042 and the first shield electrode 1044 may be in a first layer of the electric field sensor 1040, the insulating layer 1046 may be interposed between the first layer and the second shield electrode 1048. For instance, in the exploded view of FIG. 11, these three layers of the electric field sensor 1040 can be seen, with the second shield electrode 1048 as the top layer, the insulating layer 1046 as the middle layer, and the first layer includes the sense electrode 1042 and the first shield electrode 1044. The layers may be connected together, such as with an adhesive or bonding, and the insulating layer may be made from a non-conductive material, such as a fiberglass.

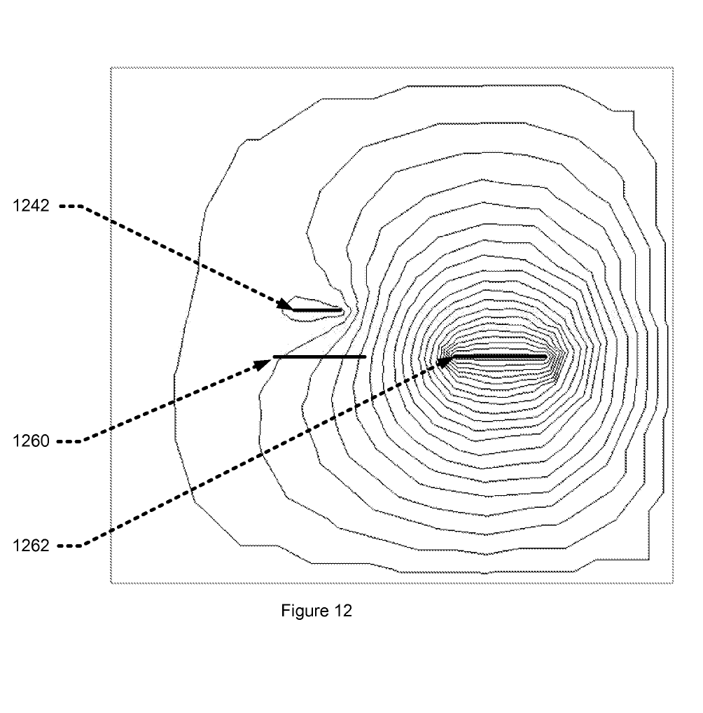

In some embodiments, the first shield electrode 1044 and the second shield electrode 1046 may reduce the amount of interference to the sense electrode 1042 that may be caused by some other voltage, such as another nearby conductor with a voltage. For instance, FIG. 12 depicts an example of electrical interference caused to the sense electrode by another conductor. A first conductor 1260 can be seen directly below the sense electrode 1242, with the second conductor 1262 on the right hand side of FIG. 12 which is producing an electric field, as represented by the mostly non-linear equipotential lines throughout FIG. 12; the equipotential lines generated by the first conductor 1260 are not shown. As can be seen, this electric field of the second conductor 1260 is causing interference to the sense electrode 1242.

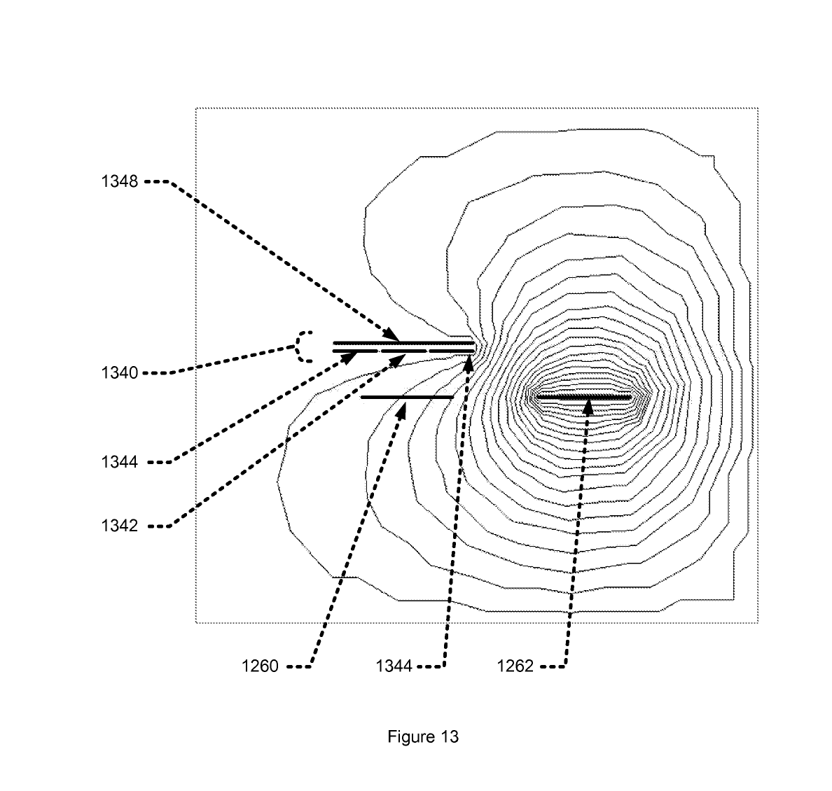

FIG. 13 depicts an example of the effect of shield electrodes on electrical interference caused to the sense electrode by another conductor from FIG. 12. FIG. 13 includes a voltage sensor 1340, similar to that discussed in FIGS. 10 and 11, which includes a sense electrode 1342, a first shield electrode 1344, and a second shield electrode 1348. This voltage sensor 1340 is placed in close proximity to the first conductor 1260 and the equipotential lines caused by the second conductor 1262 can be seen. In contrast to FIG. 12, FIG. 13 illustrates that the interference of the second conductor is reduced on the sense electrode 1342. For instance, the electric field, as represented by the equipotential lines, are not as close to the sense electrode like in FIG. 12.

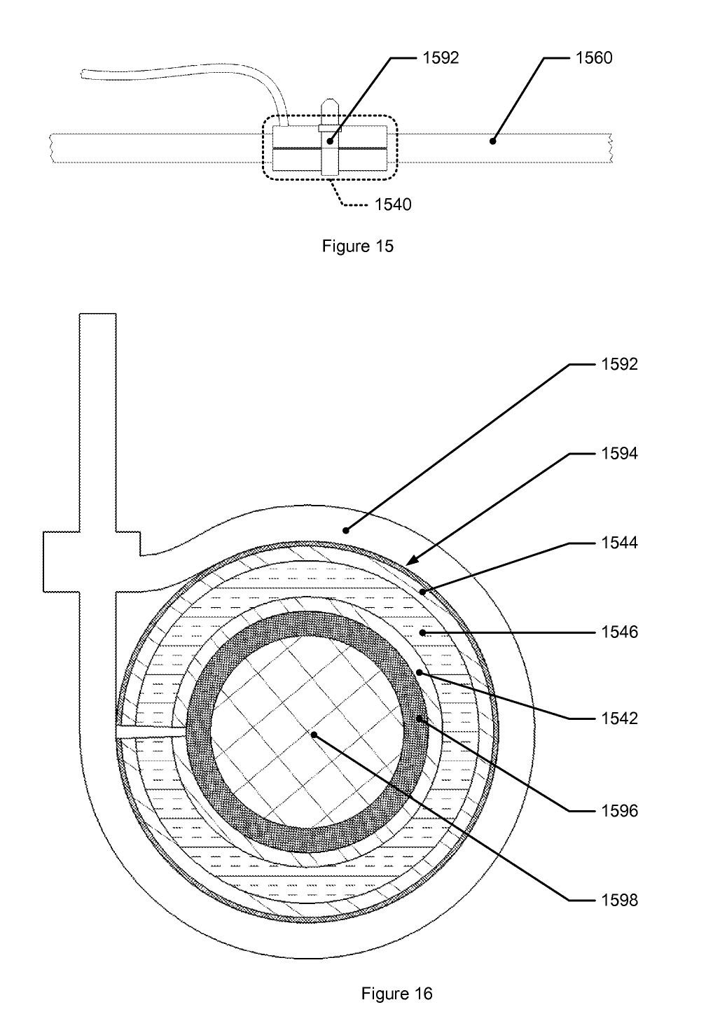

In some embodiments, the configurations of the voltage sensor may differ. For instance, there may be more than one sense electrode, there may be more or less than two shield electrodes, and/or the configurations of such items may be different that shown in FIGS. 10 through 13. A second example voltage sensor is discussed below and shown in FIGS. 15 and 16.

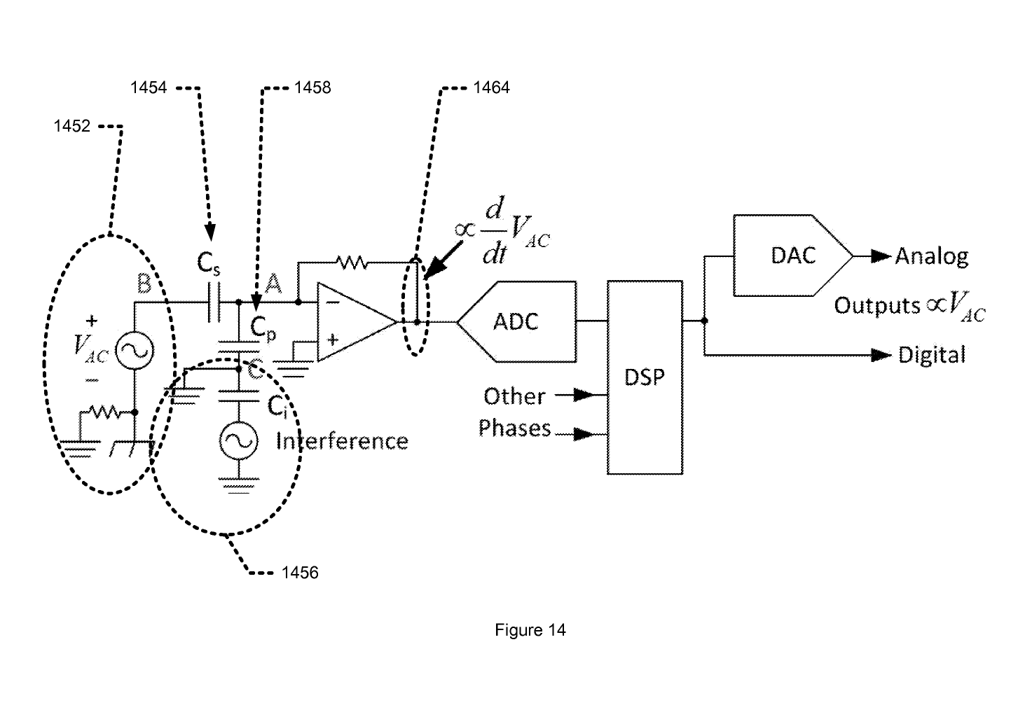

The voltage sensor may be implemented in numerous ways in order to determine a voltage. FIG. 14 depicts an electrical circuit of one example embodiment of an electric field sensor. In FIG. 14, the electrical circuit 1450 shows that the electric field sensor is electrically connected to one or more elements of a metering device, which will be discussed herein. This electric field sensor of FIG. 14 may be configured similar to or identical to the electric field sensor discussed above in FIGS. 10 and 11. To the left of node B, in a first region identified as 1452, is the voltage “V_{AC}” which is the voltage for measurement. To the immediate right of node B is a sense capacitor, identified as both “Cₛ” and 1454, which may be made up of a conductor and an electrode similar or identical to the sense electrode 1042 of FIG. 10.

Below node C, in a second region identified as 1456, is an area that generally depicts interference which may be caused by the electric field of one or more other conductors. For example, interfering signals, such as from other phases and the wider world, may couple directly to the sense electrode and introduce phase and/or magnitude errors. Example interference is shown in FIG. 13 and discussed above. The interference may be coupled into the system through an interference capacitor, labeled as “Cᵢ” formed between 1262 and 1342. In between the second region 1456 and the sense electrode 1454 is a protection capacitor labeled as “Cₚ” and 1458, e.g. one or more shield electrodes, which may be similar to the shield electrodes discussed in FIGS. 10 through 13 and that may be formed between the second conductor 1262 and one or more of the shield electrodes, such as the first shield electrode 1344 and the second shield electrode, 12NN48, or other sources of interference. Although a single electrode is shown, there may be more than one Cₚ shield electrodes in some embodiments. The location of such shield electrodes minimizes and/or eliminates interference which may be caused by one or more other conductors with flowing voltage as discussed above.

To the right of node A in FIG. 14 are one or more elements of an electronic metering device. Immediately to the right of node A are a resistor and an amplifier which may provide analog signal processing such as amplification and/or filtering. At a third region 1464 of FIG. 14, the electrical signal, which may be an analog or a digital signal, may be representative of the rate of change, e.g. the derivative, of the voltage. In order to determine a current from such a signal, the integration of the signal must be performed. This may be accomplished by a processor and/or controller that may be configured to perform such calculations. However, once the integration is performed, the signal may be distorted and/or may have a phase error, but both of these may be reduced.

To the right of the third region 1464 of FIG. 14, an analog to digital converter (“ADC”) may be seen, followed by a signal processing unit (“DSP”) which may perform some signal processing of the signal, including, among other things, the abovementioned integration, correction of the distortion, and/or correction of the phase error. The right of the DSP indicates that the output voltage from the DSP may sent as a digital signal and/or an analog signal, by the digital to analog converter unit (“DAC”). One or more of these items may be located on a non-contact metering device, while other may be located on a separate device, such as a computer, database, or other device.

In some embodiments, the voltage sensor may be configured differently than discussed above. FIG. 15 depicts a plane view of a second example electric field sensor on a conductor and FIG. 16 depicts a cross-sectional view of the second example electric field sensor and the conductor. In FIG. 15, an electric field sensor 1540 can be seen wrapped around a first conductor 1560 and secured with a first securement means 1592 which may be, like in FIG. 15, a zip-tie or adhesive-type fastener. In some embodiments, the second example electric field sensor 1540 may be configured and/or implemented in a manner similar to that of the first example electric field sensor described above as well as the electrical schematic discussed in FIG. 14. For example, in FIG. 16, a series of concentric circles may be seen which includes the cross sections of the various elements of the electric field sensor 1540 and the first conductor 1560. The outer most element is the first securement means 1592, followed by an external insulation 1594 of the voltage sensor 1540, then a first shield electrode 1544 (which may correspond to Node C of the schematic of FIG. 14), followed by an insulating layer 1546 (which in some embodiments may be a dielectric layer), then a sense electrode 1542 (which may correspond to Node A of the schematic of FIG. 14), followed by conductor insulation 1596, with the conducting wire 1598 at the center (which may correspond to Node B of the schematic of FIG. 14. As shown, the first conductor 1560 includes the conductor insulation 1596 and the conducting wire 1598.

As stated above, in some embodiments, the electrical circuit shown in FIG. 14 may be used to implement the electric field sensor shown in FIGS. 10 through 16.

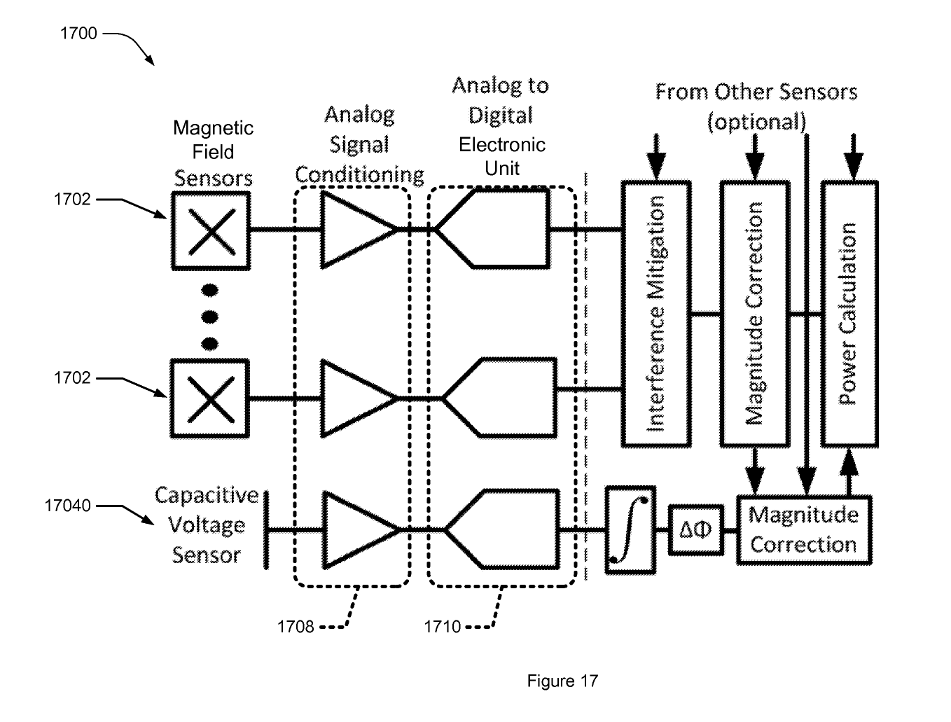

FIG. 17 depicts a schematic of an example embodiment of a non-contact metering device configured to determine a current and a voltage. Non-contact metering device 1700 is shown with two magnetic field sensors 1702, with the dots in-between these sensors indicating that additional magnetic field sensors may be included, voltage sensor 1740 which is a capacitive voltage sensor similar to those discussed above, analog signal conditioners 1708, analog to digital electronic units 1710. To the right of the analog to digital electronic units may be where signal processing may occur, which may be in the signal processing unit (not labeled) and or a controller, as discussed below. As can be seen, the device 1700 may be configured to perform additional processing which may include mitigation of interference, magnitude correction, power calculation, integration, and/or phase correction. Such processing is discussed in greater detail with this present description. In some embodiments, some or all of these elements may be included on the actual non-contact metering device configured to determine a current and a voltage, while in other embodiments, some or all of these items may be separate from the device.

In some embodiments, a non-contact metering device may include a communications and power interface electronic unit. For instance, a non-contact metering device configured to determine a voltage, a current, power and/or both a voltage and current may include the communications and power interface electronic unit. As discussed above, the device 100 includes the communications and power interface electronic unit 112. Such a unit may include one or more power sources, such as a battery, and/or a power connection for connecting to a power source in order to provide power to the device. For instance, in some embodiments the non-contact metering device may include a connection for a battery for making a single breaker data logger. This unit may also include one or more communications elements in order to communicate with an external device wirelessly and/or through a cable. For example, the communications and power interface electronic unit may include wire line serial interfaces (e.g., USB), wireless interfaces (e.g. Bluetooth, WiFi, Zigbee), or near field wireless communication. The external device may include a database, computer, other non-contact metering device, or the like.

Similarly, in some embodiments, a non-contact metering device may include a non-volatile data storage. For example, a non-contact metering device configured to determine a voltage, a current, power, and/or both a voltage and current may include the non-volatile data storage. This storage, which may be considered a “memory”, may be configured to store and/or log data from the one or more sensors of the device, instructions for controlling the processor, determining a current, determining a voltage, determining a power calculation, and/or other information that may be used to determine a current, voltage, and/or power. This non-volatile data storage may located on the non-contact metering device, such as in device 100, it may be a flash memory, and/or the storage may be located on an external device.

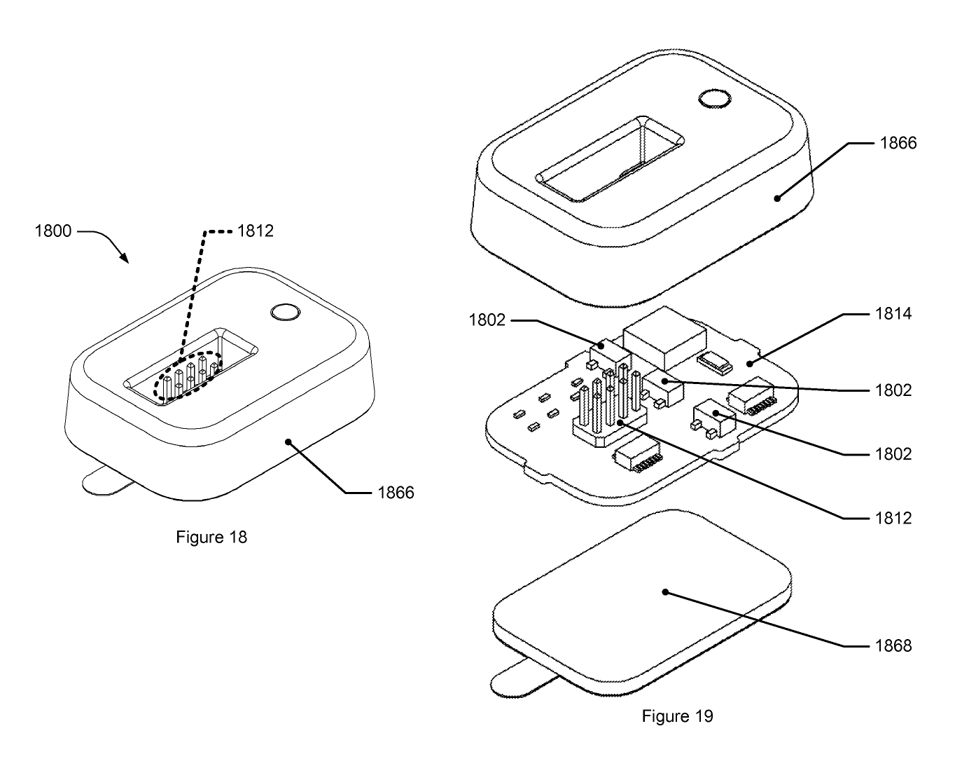

In some embodiments, a non-contact metering device may be configured to be mounted on or near a conductor. Such configuration may allow the non-contact metering device to be installed permanently and/or temporarily on or near the conductor. In some embodiments, the non-contact metering device may be configured to be mounted on a circuit breaker. FIG. 18 depicts an isometric view of a seventh example non-contact metering device. A non-contact metering device 1800 is shown and includes a housing 1866 and a portion of a communications and power interface electronic unit 1812. FIG. 19 depicts a partially exploded, isometric view of the non-contact metering device of FIG. 18. The housing 1866 can be seen, along with a circuit board 1814 which may be configured similar to the circuit board of FIG. 1 and device 100 (and in some embodiments may be an integrated circuit), such as including one or more magnetic field sensors 1802 and the communications and power interface electronic unit 1812. The circuit board 18614 may also include one or more other elements of a non-contact metering device described hereinabove, but only two are identified for illustration purposes. The device 1800 also includes a bottom 1868, which may be considered part of the housing 1866. In some embodiments, the housing 1866, the bottom 1868, and/or some other portion of the non-contact metering device 1800 may include an adhesive on a surface of the device which may enable the non-contact metering device to be mounted on or near a conductor.

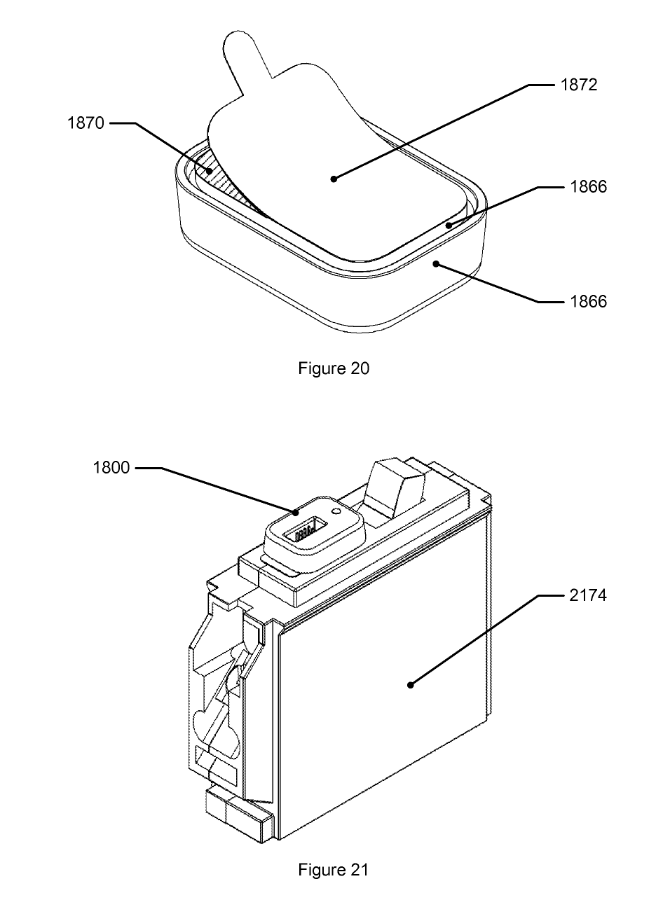

FIG. 20 depicts a different isometric view of the non-contact metering device of FIG. 18. The device 1800 in FIG. 20 is oriented such that the bottom 1868 may be viewed. In this seventh example embodiment of the non-contact metering device 1800, the bottom 1868 includes an adhesive layer 1870, indicated with crosshatching, that may be covered by a film cover 1872 such that the film cover 1872 may be removed which may expose the adhesive layer 1870 in order to mount the device 1800 onto or near a conductor.

As mentioned above, in some embodiments, the non-contact metering device of FIGS. 18, 19, and 20 may include a means of adhesion, such as a peel-and-stick adhesive, such that the device may be adhered or affixed to a solid surface, such as an electrical panel. The means of adhesion can be made of any material, such as an electrical insulator. In some embodiments, the means of adhesion is permanently adhered to the device. In some embodiments, the means of adhesion is temporary, such that, after a period of time, the device can be easily separated from the solid surface. An example means of adhesion that is temporary is Velcro® hook and loop fastener. In some embodiments, the means of adhesion is permanent, such that device is permanently adhered to the solid surface. In some such embodiments, the film cover 1872 may be the portion of the device that may be “peeled off” in order to stick the device onto a desired mounting surface.

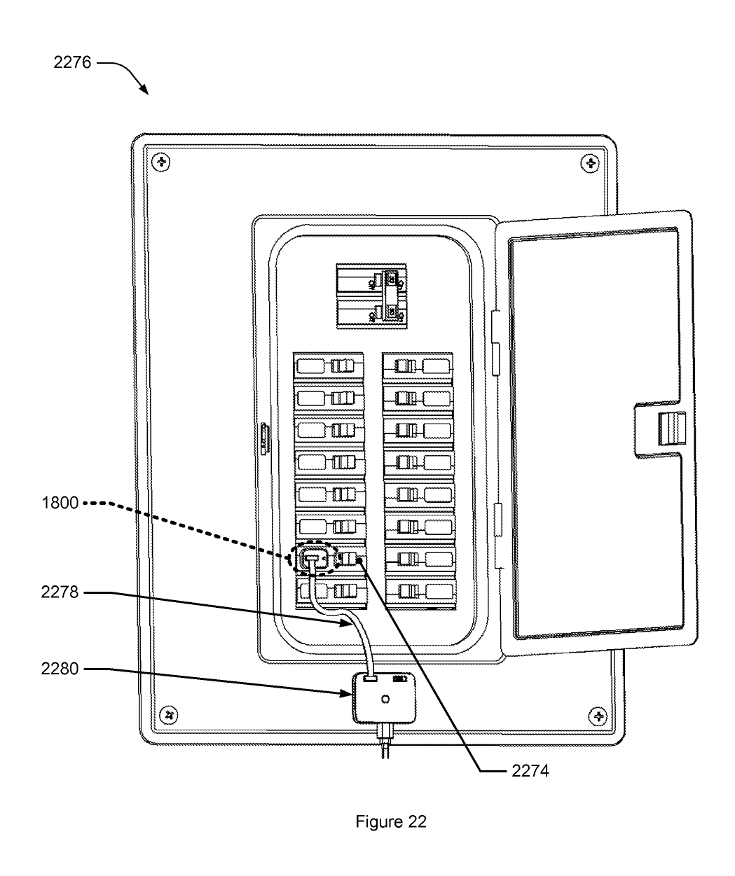

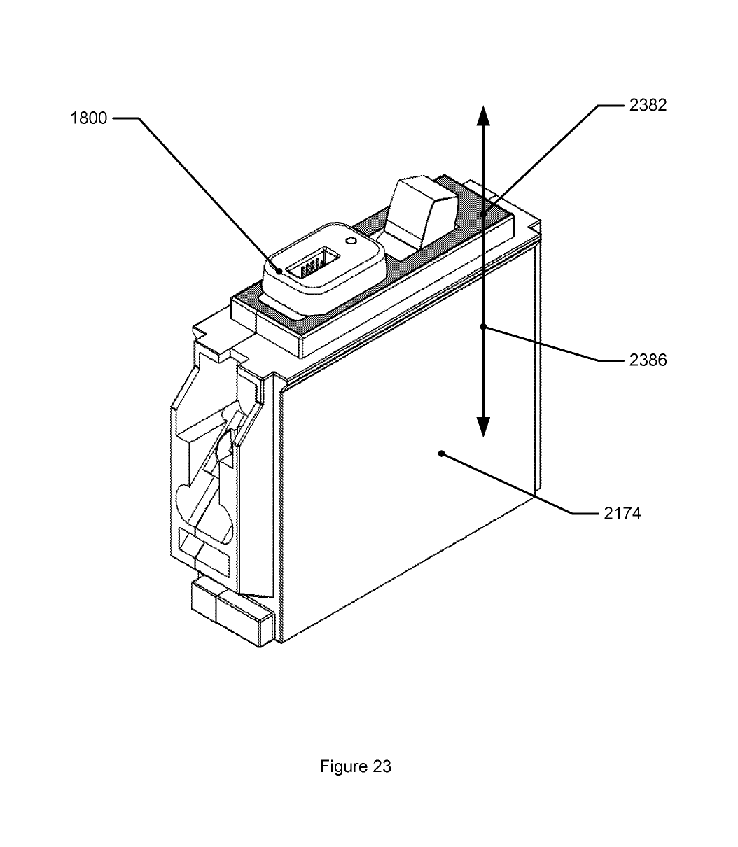

FIG. 21 depicts an isometric view of the non-contact metering device of FIG. 18 installed on a circuit breaker. As can be seen, the non-contact metering device 1800 from FIG. 18 has been mounted on a circuit breaker 2174. FIG. 22 depicts a plane view of the non-contact metering device of FIG. 18 installed on a circuit breaker that is installed on a breaker panel. In FIG. 22, the device 1800 can be seen installed on a circuit breaker 2274, and such breaker is installed in a panel of circuit breakers 2276. In some embodiments, as depicted in FIG. 22, a cable, wire, and/or other conduit 2278 or wire may be connected to the device 1800 which may be connected to a separate device 2280 external to the device 1800. In some embodiments, the separate device 2280 may include one or more of the aforementioned elements of the non-contact metering device (e.g., a device configured to determine a voltage, current, power, and/or both a voltage and a current). In some embodiments, more than one non-contact metering device, which may measure current, voltage, power, energy, and/or both current and voltage, may be mounted on a panel of circuit breakers.

In some embodiments, a non-contact metering device that may be configured to measure a current, as discussed above, may be configured such that at least one magnetic field sensor may measure the magnetic field in a direction perpendicular to a predominant direction of current flow. For example, referring back to FIG. 2, the conductor 116 may have current running through it in a direction orthogonal to the x- and y-axes, such that it may be orthogonal to the Figure, e.g. either flowing “into” or “out of” the Figure. Accordingly, the device 100 in FIG. 2 is oriented such that the magnetic field sensors 102A and 102B 1 each are able to detect the magnitude of the magnetic field in the y-direction, as indicated by directional arrows 104, which is a direction perpendicular to the flow of the current. In some embodiments, the non-contact metering device that may be configured to measure current may be configured such that at least one magnetic field sensor may measure the magnetic field in a direction that may pass through a plane of the dead front of a circuit breaker and/or circuit breaker panel. In some embodiments, the flow of current in a conductor may not be linear, like that shown in FIG. 2. In some such situations, the current flow through an item for measuring, such as a circuit breaker, may have a complex current route and/or looping pattern (e.g., a solenoid). However, in some such situations, the predominant direction of current flow at the dead front of the circuit breaker may be into or out of the plane of the panel dead front or perpendicular to the plane of the dead front.

For instance, FIG. 23 depicts an isometric view of the non-contact metering device of FIG. 18 installed on a circuit breaker of FIG. 21. Like in FIG. 21, device 1800 is installed on the breaker 2174, and an example dead front plane 2382, shown with shading, can be seen. The dead front plane 2382 represents a plane of the circuit breaker 2174 that may be one exterior surface of a circuit breaker. In some instances the dead front plane 2382 may be the same as the exterior surface of the circuit breaker 2174 that may be at least a portion of the circuit breaker 2174 that may be exposed after installation into a breaker panel. In some embodiments, the dead front plane may be parallel to the dead front plane 2382 of FIG. 23. Arrow 2384 in FIG. 23 represents a direction perpendicular to the dead front plane 2382. As noted above, the device 1800 may be installed such that one or more magnetic field sensors may measure a magnitude of the magnetic field produced by the circuit breaker 2174 in a direction perpendicular to the dead front plane 2382, which may be the direction of the arrow 2386. In some embodiments, a non-contact metering device that is located on the dead front plane of a circuit breaker may be located such that least one magnetic field sensor of the device may measure the magnetic field in a direction perpendicular to a plane of the dead front of the circuit breaker.

In some embodiments, the non-contact metering device that may be configured to measure a current, may include one or more magnetic field sensors that may measure a magnitude of the magnetic field produced by the circuit breaker 2174 in a direction within the dead front plane 2382 and perpendicular to the direction of a predominant current flow in the circuit breaker 2174. In some such embodiments, the same device may also include one or more magnetic field sensors that may measure a magnitude of the magnetic field produced by the circuit breaker 2174 in a direction perpendicular to the dead front plane 2382. Combined, such sensors may be able to mitigate interference caused by magnetic fields generated by other conductor.

In some embodiments, a non-contact metering device, which may be configured to measure current, voltage, power, energy, and/or both current and voltage, may be a part of a system. The system may include a non-contact metering device configured to determine a current, a voltage, or both a current and a voltage, like discussed herein above and shown in at least FIGS. 1 through 23. The system may also include a memory, which may be the same as the non-volatile data storage discussed above, as well as a controller. The controller may include “logic” for measuring and/or determining a current and/or a voltage, or other control logic discussed herein. The logic may be implemented as software (with or without associated hardware for executing software instructions), hardware designed or configured to carry out certain operations, and combinations thereof. In some embodiments of the system, the controller may be located on the non-contact metering device and/or on an external device such as a computer or database; similarly, the memory may be located on the non-contact metering device and/or on an external device such as a computer or database.

In some embodiments, the non-contact metering device may comprise one or more of the aforementioned components, or any combination thereof. In some embodiments, the device may further include a computer, database, and/or controller that may be configured to manage multiple sensors and pass data back to an external device, including a database or cloud-based entity.

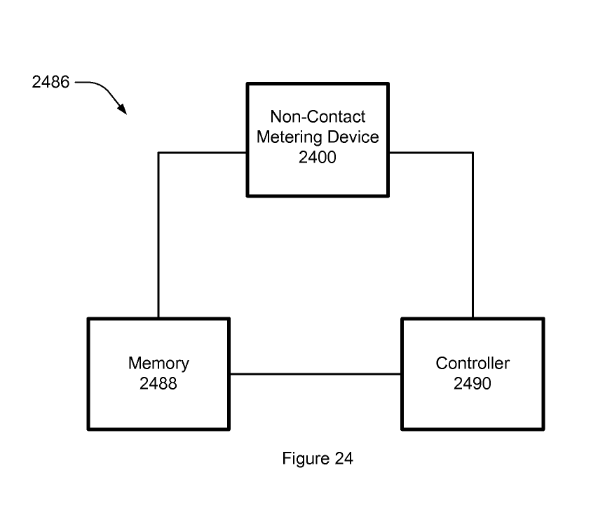

FIG. 24 depicts a first example system. As can be seen, system 2486 includes a non-contact metering device 2400, a memory 2488, and a controller 2490. Each of these items in the system may be communicatively connected to one or more other item. For instance, all three items in system 2486 are communicatively connected to each other. In some embodiments, the controller 2490 may be communicatively connected to the memory 2488 and the non-contact metering device 2400, but the memory 2488 and the non-contact metering device 2400 may not be communicatively connected to each other. As discussed herein, the controller 2490 may include a processor. In some embodiments, the controller 2490 may include the memory 2488 and the processor.

Such systems may comprise one or more non-contact metering device configured to determine a current, a voltage, power, energy, and/or both a current and a voltage, external devices such as a computer, and/or a processor. The electronics (or logic) may be referred to as the “controller,” which may control various components or subparts of the system or systems, including, but not limited to the magnetic field sensors, a signal processing electronic unit, an analog signal conditioner, an analog to digital electronic unit, and/or a communications and power interface electronic unit.

Broadly speaking, the controller may be defined as electronics having various integrated circuits, logic, memory, and/or software that receive instructions, issue instructions, control operation, perform computations, enable measurements, and the like. The integrated circuits may include components in a form that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular aspect of metering.

The controller, in some implementations, may be a part of or coupled to a computer that is integrated with, coupled to the system, otherwise networked to the system, or a combination thereof. For example, the controller may be in the “cloud” or all or a part of a computer system, which can allow for remote access of the metering. The computer may enable remote access to the system to monitor current progress of measurements and determinations of voltage, current, both current and voltage, and/or power, examine a history of such past measurements and determinations, examine trends or performance metrics, to change parameters and/or coefficients. In some examples, a remote computer (e.g. a server) can provide access and/or information to and/or from a system over a network, which may include a local network or the Internet. The remote computer may include a user interface that enables entry, viewing, and/or programming of parameters, measurements, determinations, and/or settings, which are then communicated to the system from the remote computer. In some examples, the controller receives instructions in the form of data, which specify parameters for the one or more non-contact metering devices.

In some embodiments, the controller may be configured to receive time-resolved field measurements from one or more magnetic field sensors, a voltage sensor, and/or one or more other devices/sensors, as inputs to a set of algorithms and/or techniques, as discussed at least in part herein. For instance, a first technique may compute the component of the magnetic field of a conductor, for instance a circuit breaker, of interest and a component of the magnetic field from one or more interfering signals. This first technique may combine a statistical model of the interference and the desired magnetic field with a simple electromagnetic model of the conductor of interest. Over a series of alternating current (“AC”) cycles, the electromagnetic and statistical models are refined until there is a solution that converges over many measurements and sets of conditions. Depending on a number of factors, including but not limited to interference sources and characteristics of the conductor of interest, this may takes seconds or hours. Convergence may be measured by looking at the norm of the residuals from the model, which may be the difference between the measured magnetic field and the estimated desired and interfering signals.

This first technique may also feed one or more corrected component values for a subset of the magnetic field components of the conductor of interest into a second technique. This second technique may use a simplified electromagnetic model of the breaker that may be developed using user supplied information about the breaker, such as its dimensions, current carrying capacity, nominal voltage, topology, and the like. The electromagnetic field estimates may then be applied to an inverse electromagnetic model, which may be iteratively solved to develop scale values that convert the electromagnetic field measurements into voltage and current estimates, and which may also be used to generate a first scale factor value. The first technique may also feed one or more corrected component values for a subset of the magnetic field components of the conductor of interest into a third technique.

This third technique may also be a combination of the second technique with a statistical technique that guides scale factor determination using upstream building energy data (e.g., whole building power) that can be hourly or faster, which may develop a range of scale values to search using building energy data and raw data from the first technique. The scale value range developed with technique three may be input into the second technique, which may then be iteratively solve for a revised scale factor between the first technique and the second techniques. These values may converge if there is sufficient variability in the reference meter data and/or correlation between the reference and sensor data. The third technique may achieve errors of better than 1%. The second technique may achieve errors in the range of under 10%.

In some embodiments, the controller may include control logic for determining a current. In some such embodiments, the control logic for determining a current may implement at least a part of one or more of the techniques discussed hereinabove. In some embodiments, the control logic for determining a current may include one or more of the following: (a) causing a first magnetic field sensor to take a first sample of a first magnitude of a magnetic field in a first direction at a first location, (b) causing a second magnetic field sensor to take a second sample of a second magnitude of the magnetic field in a second direction at a second location, (c) multiplying the first sample by a first coefficient from a magnetic field model, (d) multiplying the second sample by a second coefficient from the magnetic model, (e) determining a current using (c) and (d), and/or (f) storing the current in the memory. Determining a current in (e) may include the implementation and computation of the I(t)=Σₘ₌₀^{M-1}A_{B}_{ₘ}Bₘ(t) equation discussed above which may include the execution of (a) through (f).

In some embodiments, the memory may include a magnetic field model that may contain one or more coefficients for calculating a magnetic field for a conductor. The system may be configured to receive and/or store the magnetic field model. For instance, the communications and power interface electronic unit may be configured to receive and transmit the magnetic field model to the memory, which then stores the magnetic field model. The controller may include control logic for accessing, modifying, and/or using the magnetic field model for, among other things, determining a current. The system may store more than one magnetic field model. The magnetic model, as well as an interference model discussed below, may be for example, a matrix and/or a look-up table.

The system and/or non-contact metering device may include a means to convert data measured by one or more sensors into current and/or voltage waveforms. As discussed above, the one or more sensors may be configured to measure the voltage, electric field, and/or magnetic field. The conversion of the data into current and/or voltage waveforms, which may be corrected for interference and/or amplitude errors, may be performed using one or more techniques and/or methods.

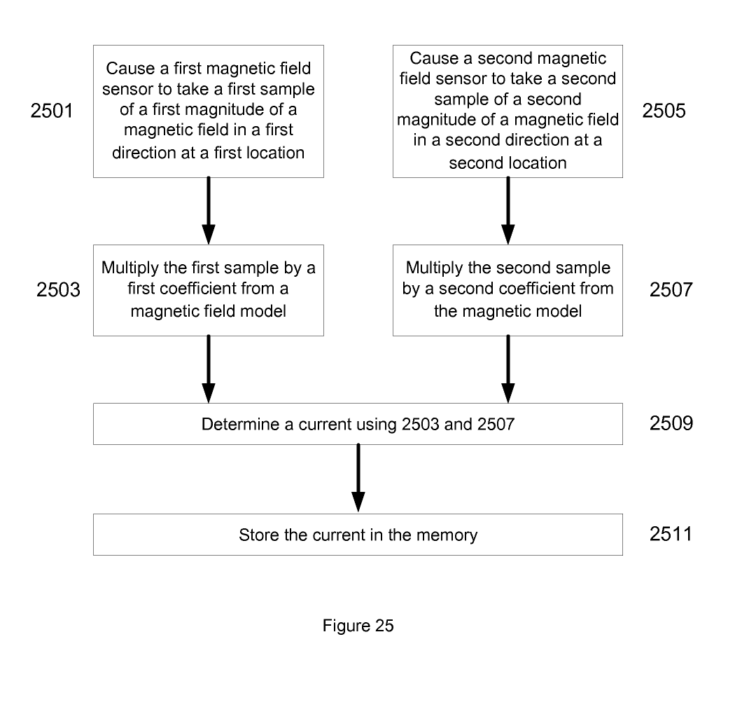

FIG. 25 depicts a flowchart illustrating one example technique of executing control logic items (a) through (f). In this example, item (a) corresponds with 2501, (b) corresponds with 2505, (c) corresponds with 2503, (d) corresponds with 2507, (e) corresponds with 2509, and (f) corresponds with 2511. In some embodiments, items 2501 and 2505 may occur at the same, or substantially the same (e.g. within +/−0.0005 seconds) from each other, 2503 and 2507 may also occur at the same, or substantially the same, time after which 2509 and 2511 may occur. In some embodiments, one or more of these items may be executed at different times and some may be repeated.

In some embodiments, items (a) through (f) may be steps and such steps may be repeated, as discussed above, at specific time intervals which may be the time period of the voltage of the waveform in an AC system. In some such embodiments, two or more of these items may be executed at substantially the same time, which, for instance, may be within +/−0.0005 seconds from each other. For example, (a) and (b) may be executed at substantially the same time as each other, while one or more of (c) through (f) may be executed at a different time than (a) and (b). Additionally, as discussed above, (a) through (f), or one or more of (a) through (f) may be executed during the aforementioned relevant time period, which may be any relevant time period, for instance every 0.017 seconds or every 50 μs. The control logic may be stored in the memory 2488 or in some other device.

In some embodiments, one or more samples taken by a magnetic field sensor may include a direct current (DC) offset. The controller 2490 may further include control logic for adjusting the DC offset of the one or more samples taken by the magnetic field sensor.

The system may also include one or more interference models. As discussed above, the interference model may include coefficients that enable the determination and/or calculation of interference that may be caused by one or more other conductors. The controller may also include control logic for storing, accessing, using, and/or modifying the interference model. For example, the controller may include control logic for (g) multiplying the first sample by a first coefficient from an interference model, (h) multiplying the second sample by a second coefficient from the interference model, (i) determining an interference measurement using (h) and (i), and/or (j) storing the interference measurement in the memory.

The controller may also include control logic for determining a more accurate current by using the interference measurement discussed above in order to reduce and/or minimizing interference. For example, the I(t) equation may be modified to reduce interference by the following equation: I(t)=Σₘ₌₀^{M-1}A_{B}_{ₘ}Bₘ(t)+I(t)=Σₘ₌₀^{M-1}C_{B}_{ₘ}Bₘ(t), where C_{B}_{ₘ} is the interference coefficient, and the controller may contain the appropriate control logic, which may include (a) through (j) for executing this equation.

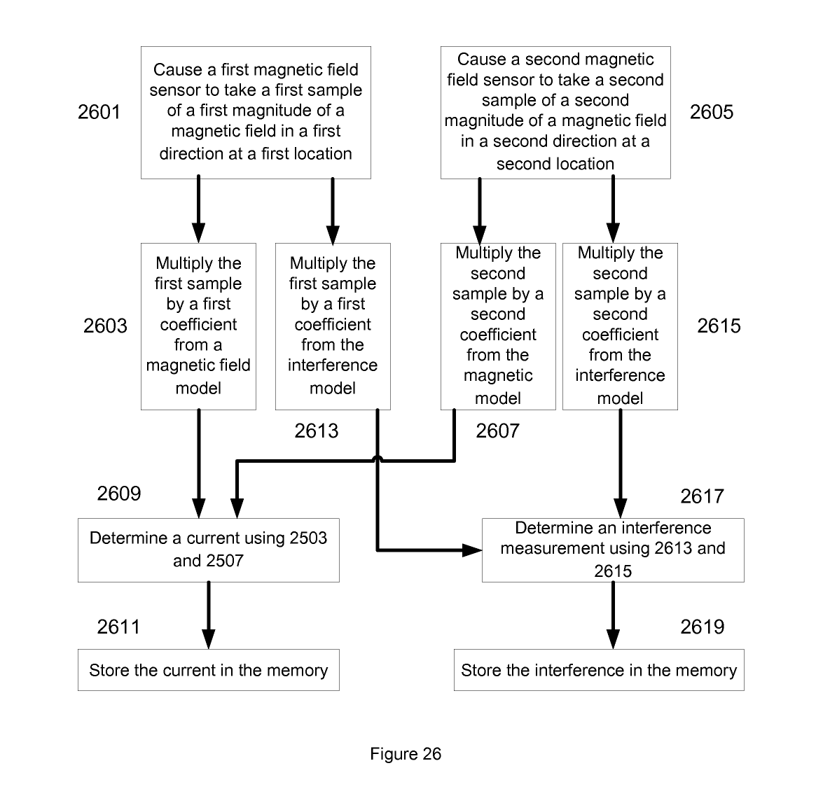

FIG. 26 depicts a flowchart illustrating one example technique of executing control logic items (a) through (f) and (i) through (l). In this example, similar to FIG. 25, item (a) corresponds with 2601, (b) corresponds with 2605, (c) corresponds with 2603, (d) corresponds with 2607, (e) corresponds with 2609, (f) corresponds with 2611, (i) corresponds with 2613, (j) corresponds with 2615, (k) corresponds with 2617, and (l) corresponds with 2619. In some embodiments, items 2601 and 2605 may occur at the same, or substantially the same (e.g. within +/−0.0005 seconds) form each other, 2603, 2607, 2613, and/or 2615 may also occur at the same, or substantially the same, time after which 2609, 2611, 2617, and/or 2619 may occur. In some embodiments, one or more of these items may be executed at different times and some may be repeated.

As discussed above, the controller may include control logic for executing and/or repeating items (a) through (f) and (i) through (l). The controller may also include control logic for determining one or more step changes that may occur between two or more currents that may be stored in the memory, and/or one or more step changes that may occur between two or more interference measurements that may be stored in the memory. A step change may be defined as a difference between two or more measurements, and such difference may be defined by any number of parameters including, but not limited to, the size of the difference, the duration of the difference, and the relative magnitude and/or sign of the difference.

The controller may also include control logic for taking additional measures and/or actions after one or more relevant step changes have been determined. In some embodiments, the controller may also include control logic for: (m) repeating one or more of (a) through (f) and (i) through (l), (n) determining one or more step changes between two or more of the currents stored in the memory, (o) determining one or more step changes between two or more of the interference measurements stored in the memory, (p) in (c), using a third coefficient from the magnetic field model, based upon the determining in (n), (q) in (d), using a fourth coefficient from the magnetic field model, based upon the determining in (n), (r) in (i), using a third coefficient from the interference model, based upon the determining in (n), (s) in (j), using a fourth coefficient from the interference model, based upon the determining in (o), (t) storing the first coefficient, second coefficient, third coefficient, and fourth coefficient from the magnetic field model in the memory, (u) storing the first coefficient, second coefficient, third coefficient, and fourth coefficient from the interference model in the memory, (v) storing the one or more step changes determined in (n), (w) storing the one or more step changes determined in (o), and (x) selecting a fifth coefficient for (c) and a sixth coefficient for (d) based at least in part upon one or more of the currents stored in the memory, the interference measurements stored in the memory, the coefficients from the magnetic field model stored in the memory, or the coefficients from the interference model stored in the memory.

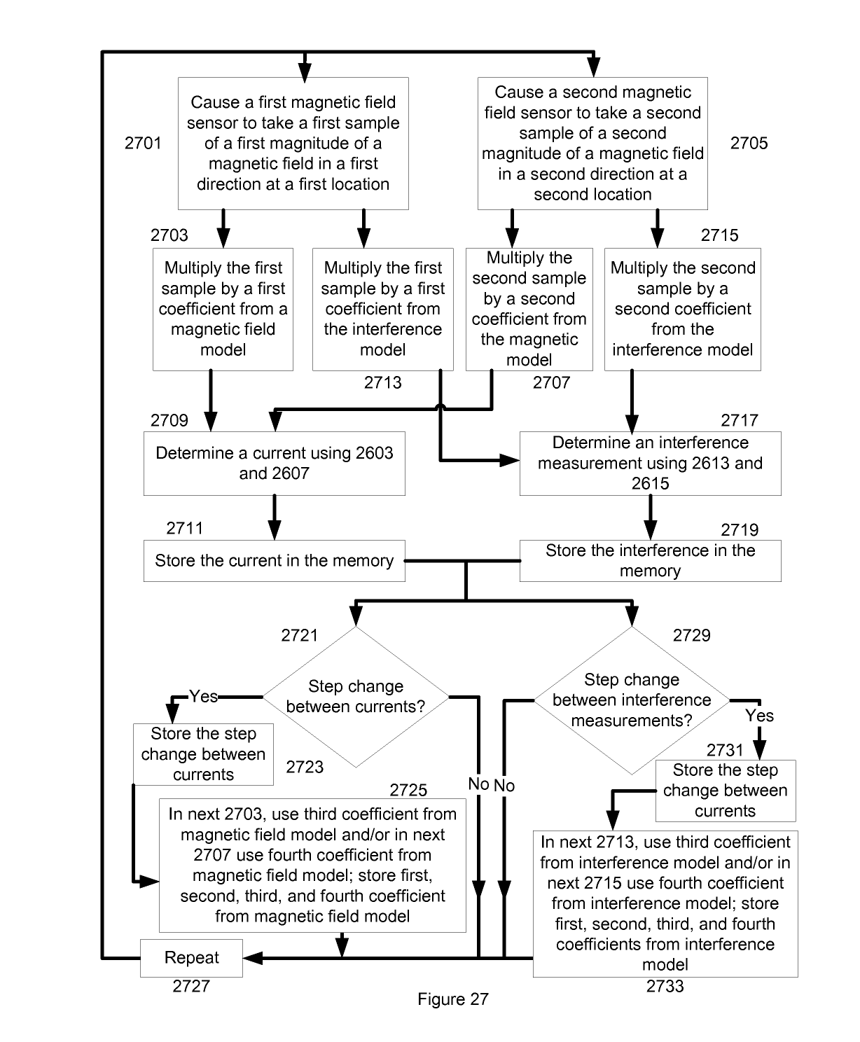

FIG. 27 depicts a flowchart illustrating one example technique of executing control logic items (a) through (f) and (i) through (w). In this example, similar to FIGS. 25 and 26, item (a) corresponds with 2701, (b) corresponds with 2705, (c) corresponds with 2703, (d) corresponds with 2707, (e) corresponds with 2709, (f) corresponds with 2711, (i) corresponds with 2713, (j) corresponds with 2715, (k) corresponds with 2717, (l) corresponds with 2719, (m) corresponds with 2727, (n) corresponds with 2721, (o) corresponds with 2729, (p) and (p) correspond with 2725, (r) and (s) correspond with 2733, (t) corresponds with 2725, (u) corresponds with 2733, (v) corresponds with 2723, and (w) corresponds with 2731. In some embodiments, some of these items may occur at the same time and/or sequentially. For instance, items 2701 and 2705 may occur at the same, or substantially the same (e.g. within +/−0.0005 seconds) form each other, 2703, 2707, 2713, and/or 2715 may occur sequentially and/or at the same, or substantially the same, time after which 2709, 2711, 2717, and/or 2719 may occur. In some embodiments, one or more of these items may be executed at different times and some may be repeated.

Following 2711 and/or 2719, a determination may be made as to whether a step change has occurred between one or more currents stored in the memory, item 2721, and/or a determination may be made as to whether a step change has occurred between interference measurements, item 2729. If no step change has occurred with either, then the technique may be repeated. However, if a step change did occur, for example between currents, then information relating to the step change may be stored in the memory 2723 and then item 2725 is executed. For example, item 2725 may cause the next iteration of 2703 and/or 2707 to use a different coefficient from the magnetic field model for multiplying against the first and/or second sample and this different coefficient may be 27 different from the first and/or second coefficients used in the previous execution of 2703 and/or 2707. Therefore, in one instance, a first execution of 2703 multiplies the first sample by the first coefficient from the magnetic field model, then later 2721 detects a step change which causes the execution of 2725, which in this instance causes the next, or second, application of 2703 to use a third coefficient from the magnetic model, not the first coefficient. In this example, the first sample is multiplied by a different coefficient in the first and the second executions of 2703. In some embodiments, 2725 may cause the use of more than 2 coefficients in multiple and later applications of 2703 and/or 2707. In some embodiments, this may be an iterative technique. Also, the first, second, third, and fourth coefficients from the magnetic model may be stored, according to item 2725. A similar technique is performed with the step change between the interference measurements, items 2729, 2731, and 2733. For instance, 2733 may cause a similar use of different coefficients from the interference model for a later, or “next”, execution of 2713 and 2715, like in 2725. After 2733 and/or 2725, the technique may be repeated.

Although not listed on FIG. 27, an additional item may occur in the technique in which a fifth coefficient for (c) and a sixth coefficient for (d) based at least in part upon one or more of the items selected from the group consisting of: the currents stored in the memory, the interference measurements stored in the memory, the coefficients from the magnetic field model stored in the memory, and the coefficients from the interference model stored in the memory. This may occur after items 2725 and/or 2733. Additionally, the technique listed in FIG. 27 may be repeated multiple times and the magnetic field coefficients and/or interference model coefficients may also be changed multiple times, and such models may contain more than four coefficients. Additionally, this may be executed in an iterative technique.

In some embodiments, the system may be configured to measure a voltage. In some such embodiments, the non-contact metering device that may be configured to determine a current may also be configured to determine a voltage using a voltage sensor. In some other embodiments, the voltage sensor may be separate from the non-contact metering device. The controller may also include control logic for (y) causing the voltage sensor to take a first sample of a voltage and (z) determining a first power measurement using the current and the first sample of the voltage. Power may be obtained by multiplying the current by the voltage.

In some embodiments, the voltage sensor of the system may be the electric field sensor discussed hereinabove and shown in at least FIGS. 10 through 16. In some such embodiments, the electric field sensor, may include a sense electrode and one or more shield electrodes, for example, similar to the electrical schematic of FIG. 14. The controller may also include control logic for determining a voltage using the electric field sensor, which may include: in (y), causing the voltage sensor to take a first sample of a rate of change of the voltage, (aa) determining the voltage using the rate of change of the voltage from (y), and (bb) determining a first power measurement using the current and the voltage from (aa). In some such embodiments, the system may be configured to remove the DC component from the electric field sensor data, integrate the result, measure a voltage at a conductor separate from a conductor of interest (e.g. an outlet of the building in which the conductor of interest is located), and/or compare the electric field sensor data to the measured voltage.

In some other embodiments, the voltage sensor of the system may be a “contact” voltage sensor. The controller may also contain logic for determining the voltage based on the measurement provided by this voltage sensor.

In some embodiments, the non-contact metering device may include the controller that may include and may be configured to execute the control logic to determine a voltage, current, and/or power, as discussed, including, for instance items (a)-(x) discussed herein above. The control logic may also be located on a memory which may be executed by a processor on a computer and/or a server/database which may be in the cloud, in a building, or another site. In some implementation, the non-contact metering device and/or system may be configured to compress the data, e.g. the measurements from the one/or more sensors and or any computations, from the non-contact metering device and/or system.

The control logic items described above, including some or all of items (a) through (x), as well as their execution and the techniques of FIGS. 25 through 27, may be implemented using one or more methods.

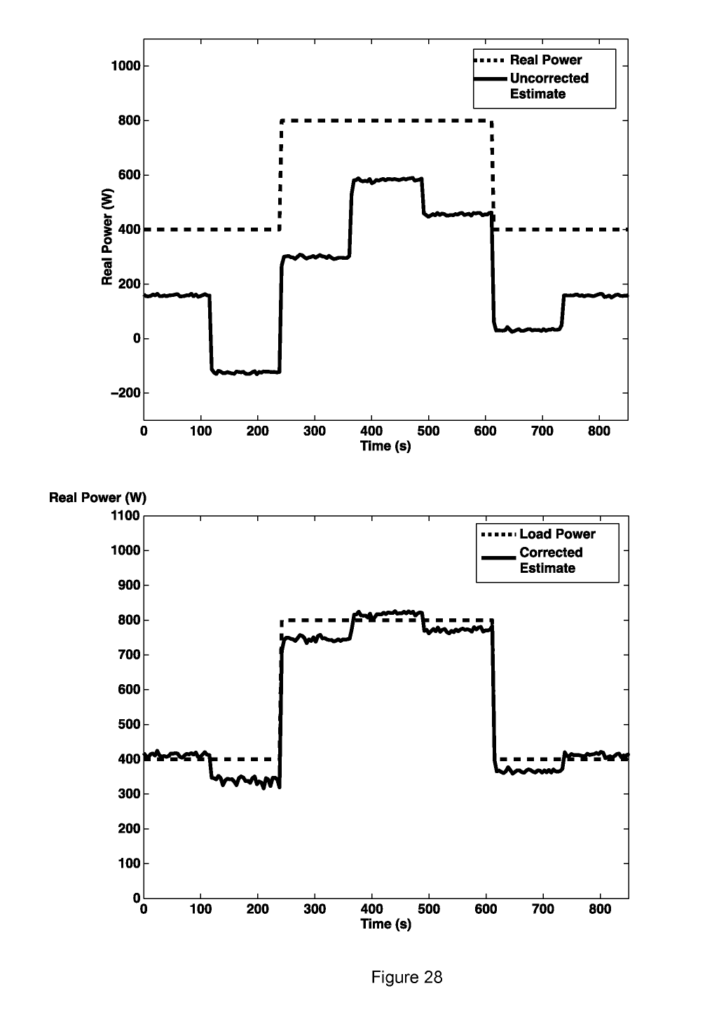

FIG. 28 depicts two graphs showing example results of power estimates calculated using an embodiment of the present disclosure. For the results shown, testing was performed using laboratory data from a non-contact metering device with a single magnetic field sensor and a single electric field sensor and electromagnetic models. The laboratory data was obtained by logging raw sensor data for one 60 Hz cycle every 10 s from each sensor. A sequence of loads was applied to the circuit breaker of interest as well as nearby breakers and the result of these measurements are shown in 28. Using the aforementioned device and at least part of the calculations, determinations, control logic, and/or techniques discussed herein, a current and a voltage were determined. Power was obtained by multiplying the current by the voltage. The top graph shows the estimated power without being corrected by some of the calculations, determinations, control logic, techniques, and/or algorithms disclosed herein, indicated by the solid line, which is offset from, i.e. lower than, the actual, real power flowing through the conductor of interest. The bottom graph shows the corrected power estimate after utilizing at least a part of the calculations, determinations, control logic, techniques, and/or algorithms discussed herein, as compared to the real power which may have an error rate of approximately 9% or less for about 80% of the measurements.

A first example implementation of the non-contact metering device and/or the system will now be discussed. In such example, a user may input a pitch between one or more conductors, which may be a circuit breaker, and may also input information about the one or more conductor, such as the general type of the breaker, the model number of the breaker, whether the conductor is part a one, two, or three pole breaker, and/or additional information about nearby beakers. This input may occur before and/or after installation of a non-contact metering device on or near a conductor of interest. The non-contact metering device and/or system may be configured to receive this input information, and depending on the configuration of the non-contact metering device and/or system, this information may be input directly to the non-contact metering device, or some a part of the system, which may include a user interface of a computer, a database, and/or other external device.

The non-contact metering device and/or system of the first example implementation may also be configured to use such input information in order to parameterize a magnetic field model which may include the creation a matrix of the current expectations and/or estimates from one or more magnetic field sensors for the conductor of interest. For instance, if the conductor of interest is a circuit breaker, then the matrix may be created for current estimates of one or more poles of a circuit breaker that may be two above or two below the desired breaker as well as for a conductor carrying current perpendicular to the current in the breaker of interest.

The non-contact metering device and/or system of the first example implementation may be further configured to average or approximate a sensitivity matrix and auto-calibration system based on the sensitivity matrix and/or to determine a current, as described at least in part herein below. This may be performed by multiplying the size measurements of the magnetic field by the inverted sensitivity matrix to yield the current in the desired conductor, which may be considered a first approximation. The non-contact metering device and/or system may be configured to multiply the inverted sensitivity matrix against every set of samples, which may be thousands of times a second, in order to produce an estimated current waveform. The RMS current may then be calculated for all the locations, which may include the desired conductor, and other conductors around the desired conductor, which may then be stored. Additional configuration may include detecting a change (e.g., a step change) in any one of the values, the examination of apparent cross sensitivity of one or more conductors that are not the desired conductor, the adjustment of the sensitivity matrix to minimize this cross sensitivity, the repetition of this technique until there may be a model that has minimal cross sensitivity. In some embodiments, the change may be a variable threshold based on numerous factors, and may be, for instance, 10%.

The non-contact metering device and/or system of the first example implementation may also be configured to calculate power using at least the resulting current waveform and a measured or estimated voltage waveform, and an energy measurement. Further configuration may also include developing an improved scaling factor for one or more conductor of interest, which may include the receipt and use of power that may be used by the conductor. For instance, if a conductor is a circuit breaker that is installed in a breaker panel, then this may include the receipt and use of power used by the panel, which may be considered the meter power. This further configuration may include sampling a sliding window of magnetic field and voltages, calculating power, and performing cross correlation between the power values and the reference meter power. The non-contact metering device and/or system of the first example implementation may be configured to then, based on one or more criteria such as a correlation better than 0.9, determine a scale factor by performing a time offset correction (using cross correlation again) of the two waveforms, removing the mean from each, and/or dividing the two waveforms. The scale factors may be stored on a memory and the non-contact metering device and/or system of the first example implementation may be configured to utilize such scale factors for determining current, voltage, and/or power.

In some embodiments, the system and/or non-contact metering device may use algorithms and/or methods for recreating a waveform that may have a value in a range, e.g., 100 V to 500V while sensing voltage at a point with a voltage magnitude different from that of the recreated voltage waveform. In some embodiments, the device may use one or more techniques for recreating a waveform that has a value over 115V or 125V. In some embodiments, the device may use one or more techniques for recreating a 208V, 277V, or 480V waveform from a measured 120V waveform. The 208V, 277V, and 480V waveforms may be found in some commercial and/or industrial buildings.

The controller, as discussed at least in part above, may be configured to execute techniques and/or methods that may be a deconvolution technique that may enable closely placed proximity-based magnetic field sensors to be calibrated and/or reliably measure current information from a sensor voltage output.

The disclosure may allow for the measurement of voltage with wide bandwidths (kHz) and high dynamic range (1000:1 or better) without contacting any uninsulated conductor. The device may provide comparable bandwidth and dynamic range to traditional sensors while eliminating the need to contact uninsulated conductors. The disclosure may also provide for a reduction in meter installation time and cost while providing comparable accuracy.

In some embodiments, the non-contact metering device and/or system may include a sensor hardware, an energy gateway hardware, one or more sensor software modules, and/or one or more energy gateway software modules and the non-contact metering device and/or system may be configured to determine a current, voltage, power, and/or any combination thereof. The sensor hardware may include one or more of the following: a magnetic field sensors, an electric field sensor, an analog interface electronic unit, an analog to digital interface electronic unit, a microprocessor, and/or a communications interface that may include a multipoint wired serial communication bus and/or a wireless inductive communication and power transfer. The energy gateway hardware may include one or more of the following: embedded computer capable of general purpose computing and networking and a communications interface compatible with the sensor hardware.

The sensor software modules may include one or more of the following: sampling of analog sensor samples that may include phase locked to voltage and/or phase locked to crystal oscillator, integration of voltage samples to correct for sensing mechanism, software selectable phase correction of voltage signal that tracks factory offset and temperature induced offset, software selectable magnitude correction of magnetic field signal, temperature compensation of magnetic sensor amplitude, inverse electromagnetic model to mitigate crosstalk and interference, statistical model to identify likely crosstalk events to provide further crosstalk mitigation, ability to accept external inputs to statistical model for crosstalk event detection, base case models for phase are: single phase and three phase configurations which may be standalone single, dual, triple breaker, panel based single, dual or triple breaker, software selectable voltage magnitude range, inverse electromagnetic model to provide current and voltage magnitude correction, real power calculation, root-mean-square voltage and current calculation, streaming of raw sensor data over communication interface, streaming of constructed voltage and current waveforms over communication interface, and/or streaming of power values at software selectable reporting periods (such as 0.1 s, 1 s, 10 s, or 60 s).

The energy gateway software modules may include one or more of the following: a configuration of sensors with all options as stated above, provide data access both as a polling client (make request over TCP socket and using HTTP), provide data access with a push method (HTTP post and TCP socket), provide data access using a Modbus client, and/or provide co-optimization framework across multiple breakers by receiving streaming data summaries and passing even notification to individual sensors, among other communication methods.

As described herein, the non-contact metering device and/or system described herein may be capable of calculating real and apparent power values, as well as automatic magnitude calibration and correction in the magnetic field which improves accuracy and reduces the need for manual, in-the-field calibration. The device and/or system is also capable of mitigating the impact of interfering electromagnetic fields to improve accuracy. The present disclosure also provides for a device useful as a non-contact voltage sensor for electricity metering applications. This allows the device to calculate voltage magnitude and relative phase angle thus allowing the calculation of real and apparent power.

In some embodiments, as described at least in part above, the device may include one or more, or all, of the following component(s): (1) one or more magnetic field sensors that may provide a measurement of field strength in a particular direction at a particular location, (2) an electric field sensor, such as a capacitive sensor, electret sensor, or another electric field sensor, (3) an analog signal processing electronic unit that may provide low-noise amplification and/or filtering while preserving the phase characteristics of the signal, (4) an analog to digital interface electronic unit that may be capable of sampling all sensors (all magnetic and electric field elements) in a time window that may be limited by the allowable phase resolution error in the system. (5) a digital signal processing electronic unit that may be capable of providing the required signal processing, optionally (6) a communications and power interface electronic unit that may be capable of providing sufficient communication bandwidth for the intended application, optionally (7) a non-volatile data storage that may be used to log local energy data measured, and optionally (8) a connection for a battery to make a local SEM a single breaker data logger.

The benefits of this non-contact metering device that may be configured to determine a current, a voltage, power, and/or energy are numerous. For example, the device may be non-contact and non-intrusive to a live conductor which enables the device to measure the currents without opening the electrical panel and/or shutting down power to a conductor or panel. This device may reducing the cost of metering and can thus lower the barrier to entry for both building owners and energy services companies. Additionally, the use of multiple magnetic field sensors may enable the measurement of a local difference of the magnetic field and thereby correct for interference and/or magnitude errors using the above described techniques and/or methods.

The electric field sensor also overcomes a technical problem encountered in designing low-cost sensor electronics for dealing with two significant error sources introduced via capacitive sensing. The two error sources are signal distortion and phase offset. The device comprises the means to analog and digital signal process by taking a sensor signal (such as small changes in electrical charge on a conductive film) and output a voltage waveform that conforms well to the actual voltage waveform of interest.

It is to be understood that, while the disclosure has been described in conjunction with the preferred specific embodiments thereof, the foregoing description is intended to illustrate and not limit the scope of the disclosure. Other aspects, advantages, and modifications within the scope of the disclosure will be apparent to those skilled in the art to which the disclosure pertains.

All patents, patent applications, and publications mentioned herein are hereby incorporated by reference in their entireties.

While the present disclosure has been described with reference to the specific embodiments thereof, it should be understood by those skilled in the art that various changes may be made and equivalents may be substituted without departing from the true spirit and scope of the disclosure. In addition, many modifications may be made to adapt a particular situation, material, composition of matter, process, process step or steps, to the objective, spirit and scope of the present disclosure. All such modifications are intended to be within the scope of the claims appended hereto.

What is claimed is:

1. A non-contact metering device configured to determine a current, the non-contact metering device comprising:
one or more magnetic field sensors; and
a signal processing electronic unit;
wherein:
the one or more magnetic field sensors are electrically connected to the signal processing electronic unit,
each of the one or more magnetic field sensors is for providing a first measurement of a first magnitude of a magnetic field in a first direction at a first location, as a first signal to the signal processing electronic unit,
each first location is different from any other first location, and
wherein the signal processing electronic unit is for determining the current using the first signal from the one or more magnetic field sensors.

2. The non-contact metering device of claim 1, further comprising two or more magnetic field sensors, wherein:
a first magnetic field sensor is for providing a first measurement of a first magnitude of the magnetic field in a first direction at a first location, as a first signal to the signal processing electronic unit, and
a second magnetic field sensor is for providing a second measurement of a second magnitude of the magnetic field in a second direction at a second location, as a second signal to the signal processing electronic unit, and
the signal processing electronic unit is for determining the current using the first signal and the second signal.

3. The non-contact metering device of claim 2, further comprising an amplifier electrically interposed between the two or more magnetic field sensors and the signal processing electronic unit; wherein the amplifier is for amplifying the first signal and the second signal.

4. The non-contact metering device of claim 2, further comprising a filter electrically interposed between the two or more magnetic field sensors and the signal processing electronic unit; wherein the filter is for filtering the first signal and the second signal.

5. The non-contact metering device of claim 2, further comprising an analog to digital electronic unit electrically interposed between the two or more magnetic field sensors and the signal processing electronic unit; wherein:
the digital electronic unit is for converting the first signal to a first digital signal and the second signal to a second digital signals, and
the signal processing electronic unit is for determining the current using the first digital signal and the second digital signal.

6. The non-contact metering device of claim 2, further comprising an analog signal processing electronic unit electrically interposed between the two or more magnetic field sensors and the signal processing electronic unit; wherein the analog signal processing unit is for amplifying the first signal and the second signal and for filtering the first signal and the second signal, while preserving the phase characteristics of the first signal and the second signal.

7. The non-contact metering device of claim 6, further comprising an analog to digital interface electronic unit electrically interposed between the analog signal processing electronic unit and the signal processing electronic unit; wherein the analog to digital interface electronic unit is for converting the first signal to a first digital signal and the second signal to a second digital signal.

8. The non-contact metering device of claim 7, wherein the analog to digital interface electronic unit is for sampling the two or more magnetic field sensors in a time window that is limited by the allowable phase resolution error in the device.

9. The non-contact metering device of claim 1, further comprising a voltage sensor; wherein:
the voltage sensor is electrically connected to the signal processing electronic unit,
the voltage sensor is for providing a first measurement of the voltage as a third signal to the signal processing electronic unit, and
wherein the signal processing electronic unit is for determining the voltage using the third signal from the electric field sensor.

10. The non-contact metering device of claim 9, wherein:
the voltage sensor is an electric field sensor that includes:
a sense electrode, and
one or more shield electrodes;
wherein:
the voltage sensor is for providing a first measurement of the electric field as a third signal to the signal processing unit, and
the one or more shield electrodes are for blocking electric field interference from one or more other voltage sources.

11. The non-contact metering device of claim 2, wherein the second magnetic field sensor is offset from the first magnetic field sensor by a first distance.

12. The non-contact metering device of claim 11, further comprising a third magnetic field sensor; wherein:
the third magnetic field sensor is for providing a third measurement of a third magnitude of the magnetic field in a third direction at a third location, as a third signal to the signal processing electronic unit, and
the third magnetic field sensor is offset from the first magnet field sensor by a third distance that is orthogonal to the first distance.

13. The non-contact metering device of claim 1, further comprising a communications and power interface electronic unit for providing communication to one or more external devices.

14. The non-contact metering device of claim 1, further comprising a non-volatile data storage for logging the first measurements, the second measurements, and the determined current.

15. The non-contact metering device of claim 1, further comprising a connection for a battery for making a local structural equation modeling (“SEM”) of a single breaker data logger.

16. A system for non-contact metering of one or more conductors, the system comprising:
a non-contact metering device configured to determine a current, including two or more magnetic field sensors;
a memory; and
a controller comprising control logic for:
(a) causing a first magnetic field sensor to take a first sample of a first magnitude of a magnetic field in a first direction at a first location,
(b) causing a second magnetic field sensor to take a second sample of a second magnitude of the magnetic field in a second direction at a second location,
(c) multiplying the first sample by a first coefficient from a magnetic field model,
(d) multiplying the second sample by a second coefficient from the magnetic model,
(e) determining a current using (c) and (d), and
(f) storing the current in the memory;
wherein:
the non-contact metering device is communicatively connected to the controller, and
the controller is communicatively connected to the memory.

17. The system of claim 16, wherein the controller further comprises control logic for:
(g) adjusting the first sample for a first direct current (DC) offset, and
(h) adjusting the second sample for a second DC offset.

18. The system of claim 16, wherein the controller further comprises control logic for:
(i) multiplying the first sample by a first coefficient from an interference model,
(j) multiplying the second sample by a second coefficient from the interference model,
(k) determining an interference measurement using (i) and (j), and
(l) storing the interference measurement in the memory.

19. The system of claim 18, wherein the controller further comprises control logic for:
(m) repeating one or more of (a) through (f) and (i) through (l),
(n) determining one or more step changes between two or more of the currents stored in the memory,
(o) determining one or more step changes between two or more of the interference measurements stored in the memory,
(p) in (c), using a third coefficient from the magnetic field model, based upon the determining in (n),
(q) in (d), using a fourth coefficient from the magnetic field model, based upon the determining in (n),
(r) in (i), using a third coefficient from the interference model, based upon the determining in (o),
(s) in (j), using a fourth coefficient from the interference model, based upon the determining in (o),
(t) storing the first coefficient, second coefficient, third coefficient, and fourth coefficient from the magnetic field model in the memory,
(u) storing the first coefficient, second coefficient, third coefficient, and fourth coefficient from the interference model in the memory,
(v) storing the one or more step changes determined in (n),
(w) storing the one or more step changes determined in (o), and
(x) selecting a fifth coefficient for (c) and a sixth coefficient for (d) based at least in part upon one or more of the items selected from the group consisting of: the currents stored in the memory, the interference measurements stored in the memory, the coefficients from the magnetic field model stored in the memory, and the coefficients from the interference model stored in the memory.

20. The system of claim 16, wherein:
the non-contact metering device configured to determine a current is also configured to determine a voltage, and further includes a voltage sensor, and
the controller further comprises control logic for:
(y) causing the voltage sensor to take a first sample of a voltage, and
(z) determining a first power measurement using the current and the first sample of the voltage.

21. The system of claim 20, wherein:
the voltage sensor comprises an electric field sensor, including a sense electrode and one or more shield electrodes, and
the controller further comprises control logic for:
in (y), causing the voltage sensor to take a first sample of a rate of change of the voltage,
(aa) determining the voltage using the rate of change of the voltage from (y), and
(bb) determining a first power measurement using the current and the voltage from (aa).

22. A non-contact metering device configured to determine a voltage, the non-contact metering device comprising:
an electric field sensor that includes:
a sense electrode, and
one or more shield electrodes; and
a signal processing electronic unit;
wherein:
the electric field sensor is electrically connected to the signal processing electronic unit,
the electric field sensor is for providing a first measurement of the electric field as a first signal to the signal processing unit,
the one or more shield electrodes are for blocking electric field interference from one or more other voltage sources, and
wherein the signal processing electronic unit is for determining the voltage using the third signal from the electric field sensor.

23. A method for metering, the method comprising:
(a) causing a first magnetic field sensor to take a first sample of a first magnitude of a magnetic field in a first direction at a first location,
(b) causing a second magnetic field sensor to take a second sample of a second magnitude of the magnetic field in a second direction at a second location,
(c) multiplying the first sample by a first coefficient from a magnetic field model,
(d) multiplying the second sample by a second coefficient from the magnetic model,
(e) determining a current using (c) and (d), and
(f) storing the current in a memory;
wherein:
a non-contact metering device is communicatively connected to a controller, and
the controller is communicatively connected to the memory.

24. The method of claim 23, further comprising:
(g) adjusting the first sample for a first direct current (DC) offset, and
(h) adjusting the second sample for a second DC offset.

25. The method of claim 23, further comprising:
(i) multiplying the first sample by a first coefficient from an interference model,
(j) multiplying the second sample by a second coefficient from the interference model,
(k) determining an interference measurement using (i) and (j), and
(l) storing the interference measurement in the memory.

26. The system of claim 25, further comprising:
(m) repeating one or more of (a) through (f) and (i) through (l),
(n) determining one or more step changes between two or more of the currents stored in the memory,
(o) determining one or more step changes between two or more of the interference measurements stored in the memory,
(p) in (c), using a third coefficient from the magnetic field model, based upon the determining in (n),
(q) in (d), using a fourth coefficient from the magnetic field model, based upon the determining in (n),
(r) in (i), using a third coefficient from the interference model, based upon the determining in (o),
(s) in (j), using a fourth coefficient from the interference model, based upon the determining in (o),
(t) storing the first coefficient, second coefficient, third coefficient, and fourth coefficient from the magnetic field model in the memory,
(u) storing the first coefficient, second coefficient, third coefficient, and fourth coefficient from the interference model in the memory,
(v) storing the one or more step changes determined in (n),
(w) storing the one or more step changes determined in (o), and
(x) selecting a fifth coefficient for (c) and a sixth coefficient for (d) based at least in part upon one or more of the items selected from the group consisting of: the currents stored in the memory, the interference measurements stored in the memory, the coefficients from the magnetic field model stored in the memory, and the coefficients from the interference model stored in the memory.

27. The method of claim 23, further comprising:
(y) causing a voltage sensor to take a first sample of a voltage,
(z) determining a first power measurement using the current and the first sample of the voltage.

28. The method of claim 27, further comprising:
in (y), causing the voltage sensor to take a first sample of a rate of change of the voltage,
(aa) determining the voltage using the rate of change of the voltage from (y), and
(bb) determining a first power measurement using the current and the voltage from (aa), wherein the voltage sensor comprises an electric field sensor that includes a sense electrode and one or more shield electrodes.
